(19) United States
(12) Patent Application Publication
(10) Pub. No.: US 2019/0326459 A1
(43) Pub. Date: Oct. 24, 2019

(54) SINGLE-CELL ENCAPSULATION AND FLEXIBLE-FORMAT MODULE ARCHITECTURE AND MOUNTING ASSEMBLY FOR PHOTOVOLTAIC POWER GENERATION AND METHOD FOR CONSTRUCTING, INSPECTING AND QUALIFYING THE SAME

(71) Applicant: Tessolar Inc., Woburn, MA (US)

(72) Inventors: Jacob Van Reenen Pretorius, Austin, TX (US); Michael Ross Everman, Santa Barbara, CA (US); Leslie G. Fritzemeier, Lexington, MA (US); Marco Ferrara, Boston, MA (US)

(21) Appl. No.: 16/376,157

(22) Filed: Apr. 5, 2019

Related U.S. Application Data
(62) Division of application No. 15/579,192, filed on Dec. 1, 2017, now abandoned.
(60) Provisional application No. 62/169,938, filed on Jun. 2, 2015.

(51) Int. Cl. H01L 31/048; H01L 31/05; H01L 31/0224

(52) U.S. Cl. CPC H01L 31/048; H01L 31/0504; Y02E 10/50; H01L 31/022425; Y02B 10/12; H01L 31/0508

(57) ABSTRACT

A method for encapsulating photovoltaic cells into single functional units is described. These units share the mechanical and electric properties of the encapsulation layers and allow for flexible module architecture to be implemented at the cell level. This enables cost reduction and improved performance of photovoltaic power generation.

### RELATED APPLICATIONS

This application is a divisional of copending U.S. patent application Ser. No. 15/579,192, filed Dec. 1, 2017, entitled SINGLE-CELL ENCAPSULATION AND FLEXIBLE-FORMAT MODULE ARCHITECTURE AND MOUNTING ASSEMBLY FOR PHOTOVOLTAIC POWER GENERATION AND METHOD FOR CONSTRUCTING, INSPECTING AND QUALIFYING THE SAME, which is a U.S. National Phase of International Patent Application Serial No. PCT/US2016/035462, entitled SINGLE-CELL ENCAPSULATION AND FLEXIBLE-FORMAT MODULE ARCHITECTURE AND MOUNTING ASSEMBLY FOR PHOTOVOLTAIC POWER GENERATION AND METHOD FOR CONSTRUCTING, INSPECTING AND QUALIFYING THE SAME, filed Jun. 2, 2016, which claims the benefit of U.S. Provisional Application Ser. No. 62/169,938, entitled SINGLE-CELL ENCAPSULATION AND FLEXIBLE-FORMAT MODULE ARCHITECTURE AND MOUNTING ASSEMBLY FOR PHOTOVOLTAIC POWER GENERATION AND METHOD FOR CONSTRUCTING, INSPECTING AND QUALIFYING THE SAME, filed Jun. 2, 2015, the entire disclosure of each of which applications are herein incorporated by reference.

### FIELD OF THE INVENTION

This invention relates to photovoltaic cell, module and mounting hardware manufacturing techniques that increase the robustness, throughput, performance and flexibility of cells and modules to overall reduce the cost of producing electricity from solar panels.

### BACKGROUND OF THE INVENTION

As mankind continues to develop around the world, the demand for energy rises. Most energy used to power machines and generate electricity is derived from fossil fuels, such as coal, natural gas or oil. These supplies are limited and their combustion causes atmospheric pollution and the production of Carbon Dioxide, which is suspected to accelerate the greenhouse effect and lead to global climate change. Some alternative approaches to produce energy include the harnessing of nuclear energy, wind, moving water (hydropower), geothermal energy or solar energy. Each of these alternative approaches has drawbacks. Nuclear power requires large capital investments and safety and waste disposal are concerns. Wind power is effective, but wind turbines require a windy site, often far away from grid connections and take up large footprints of land. Hydropower requires the construction of large, potentially environmentally harmful dams and the displacement of large volumes of flowing water. Geothermal power requires a source of energy that is relatively near the surface—a characteristic not common to a large portion of the Earth—and has the potential to disrupt the balance of forces that exist inside the Earth's crust. Solar is one of the cleanest and most available forms of renewable energy and it can be harnessed by direct conversion into electricity (solar photovoltaic) or by heating a working fluid (solar thermal).

Solar photovoltaic (PV) technology relies on the direct conversion of solar power into electricity through the photoelectric effect: solar radiation's quantized particles, or photons, impinging on semiconductor junctions may excite pairs of conduction electrons and valence holes. These charged particles travel through the junction and may be collected at electrically conductive electrodes to form an electric current in an external circuit.

Photovoltaic is one of the most promising technologies for producing electricity from renewable resources, for a number of reasons: 1. The photovoltaic effect in Si and other solid-state semiconductors is well understood and the technology fully validated; 2. PV power plants convert directly solar power into electrical power, have no moving parts and require low maintenance; 3. Solar radiation is quite predictable and is maximum during hours of peak electricity consumptions; and 4. The industry has been aggressively pursuing a performance improvement and cost reduction path similar to the Moore's law in semiconductor electronics, approaching the condition of market competitiveness with traditional energy resources in many parts of the world. In 2015, over 60 GW of solar photovoltaic will be installed globally, continuing strong year over year growth from about 50 GW of global installations in 2014.

However, a number of significant issues remain to be solved for photovoltaic to become a mainstream source of electricity in unsubsidized market conditions: 1. PV is still more expensive than traditional energy resources in most parts of the world: while economy of scale and low cost manufacturing will contribute to further reduce cost, technological innovation is needed to achieve market competitiveness more rapidly and on an economically sound and sustainable basis; 2. Manufacturing throughput is still largely inadequate for the potential market need; 3. Mainstream PV performs poorly in a number of real-world conditions, such as low-light, diffused light, partial shading, temperature excursions, etc.; and 4. As PV cell performance continues to increase and the costs of PV modules continue to drop, installation costs consisting of hardware and labor are proportionally increasing their contribution to the total installed costs of PV power plants.

Therefore, a technology would be desirable which can decrease the cost of photovoltaic energy, increase the throughput and flexibility of PV module manufacturing, reduce the cost of installation and resolve a number of the performance issues, while being compatible with the industry value chain. It is also desirable to provide technology, devices and techniques that provide durable and long-lasting PV cells and modules.

### SUMMARY OF THE INVENTION

This invention overcomes disadvantage of prior art by providing a system and method that alleviates, for example, the breakage and degradation of PV cells in manufacturing lines; the lack of flexibility in module format and characteristics; and the performance limitations of current PV module architectures. Illustratively, a photovoltaic (PV) device is provided. The device is constructed using Single Cell Encapsulation (SCE), according to various embodiments and the assembly of the individually encapsulated cells into a module. Illustratively, by encapsulating individual PV cells of various dimensions in a multilayer structure comprising a bottom layer, a layer of encapsulant, the PV cell, another layer of encapsulant and the top layer, many benefits including flexible architecture, automated manufacturing, low cell breakage, cell and structure decoupling, etc., can be realized.

The bottom layer can consist of various materials (e.g. metals, plastic, glass, etc.), which are chosen in order to optimize mechanical, electrical and thermal transfer properties.

The top layer can consist of various transparent materials (e.g. glass, plastic, Teflon, etc.), which are chosen in order to optimize optical, mechanical, electrical and thermal transfer properties.

Electric contacts on the front and back of the cell can be already present on the cell or may be applied during single cell encapsulation. In each alternative, the contacts are illustratively extended to reach outside of the sealed structure and can be connected to an external connector, another cell's electrodes, circuitry or any conductor. The electric contacts can be of standard PV interconnect ribbon constructed, by way of non-limiting example, from tin or silver coated copper, bare copper, surface textured copper for advanced light capturing, thin silver nano-wire mesh or any other type of electric contact that can remove charge from the cell.

According to an illustrative embodiment, individual cells are plugged into (operatively connected to) a Flexible-format Module Architecture (FMA). FMA consists of a supporting sub-structure (also termed a “frame” or “framework”) that can be made from various materials formed with associated manufacturing process and dimensions. The FMA can incorporate slots or mounting pads for the insertion and support of the cells, electrical connections among the cells, power conditioning or other electronics and provision for the integration of mounting solutions. Illustratively, the FMA can allow cells to be replaced when worn or non-functional, or otherwise electrically bypassed without compromising the function of the remaining cells in the FMA.

The sub-structure, frame or framework of the FMA can incorporate features that ease the installation of PV modules in the field, on a roof or on any structure. The sub-structure can also allow for factory pre-assembly of modules, integrating a large number of cells, cells oriented in preferred direction or orientation or any other customized form for specified functions.

In various illustrative embodiments, a platform or assembly seat for fabrication of a solar PV module is provided. This platform includes a sub-structure and one or more solar cells. The solar cells are illustratively interconnected to provide electrical power and the sub-structure is constructed and arranged to provide physical protection and support to individual ones of the solar cells. Illustratively, the solar cells are each individually encapsulated and the sub-structure includes an integral joint assembly to join a mounting structure or to adjacent sub-structures. The sub-structure can include a composite material. The composite material can comprise a thermoplastic, and thermoplastic can include PET and/or glass fibers. The glass fibers can be continuous and/or can be chopped, with an aspect ratio of length-to-diameter greater than approximately 10. The materials of the sub-structure can be constructed and arranged to be resistant to ultraviolet light and/or flame retardant. Illustratively, the sub-structure can be constructed by a low-cost thermoplastic process, and can be positioned at a location corresponding to a back sheet of a conventional PV module. The joint assembly can be constructed and arranged for direct mounting to roof integrated hardware. The joint assembly can be constructed and arranged to provide a direct connection to pylons of a ground mounted system. The sub-structure can also be constructed and arranged to allow factory pre-assembly of multiple modules into larger systems that contain predetermined structural support and to allow for assembly of a multi-module onto field-installed footings. Illustratively, the solar cells can be individually, optimally inclined for a specified location and connected so that a center of gravity of the module enables mounting thereof onto a single axis tracker. Between 2 and 2,000 solar cells (per-module, by way of non-limiting example) can be assembled and interconnected. Note, further, that the number of cells-per-module and overall number of modules is highly variable and not limited by a specific parameter. The sub-structure can be constructed and arranged to enclose or attach wiring and/or to allow for integration of electrical storage devices. The sub-structure can include an integrated junction box, an integrated micro inverter, cell-level electronics and/or integrated busbars and tabs, constructed and arranged to interconnect to the solar cells. The sub-structure is also illustratively constructed and arranged to be optimized so as to reduce weight thereof while maintaining structural integrity thereof. The arrangement can be free of exposed metallic components. In embodiments, the sub-structure is ungrounded and constructed and arranged to reduce potential induced degradation of PV modules in the ungrounded state. Also, the sub-structure can be constructed and arranged to optimize packing density of modules for shipping cost reduction.

A method for encapsulating solar cells is provided in illustrative embodiments. This method includes the step of providing a source of silicone encapsulant, applying silicone to the solar cells in an amount that efficiently generates a layer of encapsulant on each of the solar cells. In this manner, an amount of silicone utilized for the encapsulant provides an economically viable production process. The step of applying the silicone reduces glass bowing during encapsulation of each of the solar cells, and can include encapsulating individual ones of the solar cells. Illustratively, a thickness of silicone between an edge of each of the solar cells and an outer edge of the encapsulant layer is no more than approximately 1.5 mm so as to allow cells to be packaged within 3 mm of each other in a module. A plurality of electrically interconnected solar cells can be constructed according to the above method for encapsulating. The solar cells can include an edge exclusion that is no more than 5 mm. Illustratively, the silicone provides a high transparency so as to optimize light transmission to the solar cells. The solar cells and connections between solar cells can be constructed and arranged to withstand string voltages of at least (e.g.) 1500 V. The photovoltaic module can be constructed and arranged to reduce degradation of the module electricity generation potential over time.

In illustrative embodiments, a method for continuous encapsulation of solar cells is also provided. This method includes the steps of arranging solar cells so as to provide for the inspection and qualification (steps of inspecting and qualifying) of each individual one of the solar cells, and encapsulating the arranged solar cells so that, after encapsulation, and before integration of encapsulated solar cells into a PV module, each of the encapsulated solar cells can be inspected and qualified. The inspection and qualification can include performing an electroluminescence test and/or a solar simulation (IV) test. Results of the inspection and qualification can provide a decision on Maximum Open Circuit Voltage, Closed Circuit Current, Fill Factor and efficiency of the encapsulated cell. The results of the inspection and qualification can also provide a decision on utility of the encapsulated cell and/or enable sorting of the encapsulated solar cells based upon performance thereof. The continuous encapsulation can comprise a lean manufacturing process in illustrative embodiments. The method can further include constructing the PV module to contain the encapsulated solar cells, so as to exhibit similar response to light to enable a manufacturing yield with a statistically higher performing module with a tighter distribution. The encapsulant can comprise silicone. Additionally, the method can include connecting tabs of the solar cells to cell busbars using a solderless process. The illustrative solderless process can utilize advanced light capturing ribbons. The method can also include utilizing conductive adhesive to electrically connect the ribbons to the solar cells. In various embodiments, the method can include electrically connecting the ribbons to the solar cells using direct connections. The method can include the use of solar cells with substantially reduced silver content or the elimination of busbars on the cells. The method is generally adapted to reduce manufacturing-induced defects in the solar cells. The arrangement can include a Non-Fluorinated back sheet and the solar cells can include individual glass having chamfers on edges thereof constructed and arranged to optimally refract light falling between the solar cells.

In illustrative embodiments a mounting structure for a solar PV module is provided. The mounting structure includes a mounting assembly constructed and arranged to be attached to a rooftop, free of (without or avoiding) penetration of the rooftop weatherization layer. The mounting structure can further include a sheet-shaped foot with one or more locking members configured to lock into a solar module. The mounting structure can be constructed and arranged to replace conventional rooftop weatherization structures, and/or is constructed and arranged to be located under an existing composite shingle and physically attached to a supporting structure of the rooftop. The mounting structure can also be constructed and arranged to be attached to the rooftop by adhesively bonding to the weatherization layer, and/or to be attached to the rooftop by fastening through the sheet-shaped foot, into an underlying structure of the roof and beneath the rooftop weatherization layer. Illustratively, the sheet-shaped foot is constructed and arranged to conform to a profile of a clay tile roof for mounting thereto. The locking members can respectively define differing heights to allow the module to be mounted with a tilt in a favorable position with respect to a position of the sun. Illustratively the mounting structure includes a composite material. The composite material can include a thermoplastic, such as, but not limited to, PET. The composite material can include glass fibers that are continuous and/or chopped with an aspect ratio of length-to-diameter greater than approximately 10. The composite material can be resistant to ultraviolet (UV) light and/or is flame-retardant. Illustratively the arrangement can include solar cells that are individually encapsulated before integration into a sub-structure, the sub-structure being operatively connected to the mounting structure.

### BRIEF DESCRIPTION OF THE DRAWINGS

The invention description below refers to the accompanying drawings, of which:

FIG. 1 is an expanded perspective view showing layers comprising an individually encapsulated photovoltaic cell and a complete cell assembly;

FIGS. 2A-2D. are perspective views showing a plurality of possible implementations of SCE bottom layer according to various embodiments;

FIGS. 3A-3C are perspective views showing a plurality of possible implementations of SCE bottom electrode according to various embodiments;

FIGS. 4A-4D are perspective views showing a plurality of possible implementations of SCE top layer according to various embodiments;

FIGS. 5A-5D are perspective views showing a plurality of possible arrangements of SCE top electrode according to various embodiments;

FIGS. 6A-6C show side cross-sections of SCE top layer according various embodiments;

FIG. 7 is an exposed perspective view of a complete cell with electric connector according to an illustrative embodiment;

FIG. 8 is a side cross section of an interconnection method between adjacent SCEs according to an illustrative embodiment;

FIG. 9 is a perspective view showing the insertion of an individually encapsulated cell in the Flexible-format Module Architecture (FMA) according to the illustrative embodiment;

FIGS. 10A and 10B are plan views, respectively, showing a generalized series connection of the cells in the FMA and bypass diodes at the cell level;

FIGS. 11A and 11B are plan views, respectively, showing an implementation of a generalized parallel connection of the cells in the FMA and power-conditioning electronics at the cell level;

FIGS. 12A and 12B are plan views, respectively, showing an illustrative implementation of a hybrid series-parallel connection of the cells in the FMA and power conditioning electronics at each sub-group in parallel;

FIG. 13 is a flow diagram showing one illustrative method to manufacture SCE where solar cells are already connected with the SCE top and bottom electrodes;

FIG. 14 is a flow diagram showing one illustrative method to manufacture SCE where the interconnection of the solar cell and the SCE top and bottom electrodes is formed during encapsulation;

FIG. 15 is a flow diagram of an alternative manufacturing process for SCE;

FIG. 16 is a perspective view of an alternate embodiment of a FMA sub-structure and close-up of the sub-structure construction;

FIG. 17A is a perspective view of an illustrative roof mounting hardware integrated into the module sub-structure;

FIG. 17B is a perspective view of the roof-mounted beams that selectively engage the hardware of FIG. 17A;

FIG. 17C is a side view of the assembled hardware of FIG. 17A and beams of FIG. 17B;

FIG. 18A is a perspective view of an illustrative ground mounting hardware integrated into the module sub-structure showing a partial assembly of modules thereto;

FIG. 18B is a perspective view of a functionally similar mounting system to that depicted in FIG. 18A, taken from a different viewing angle and in which the racking system includes FMA;

FIG. 18C is a bottom-oriented perspective view of the assembly of FIG. 18B;

FIG. 19 is a side view of an illustrative embodiment for optimally oriented cells for a single axis tracker application;

FIG. 20 is a diagram showing advanced light capturing due to light edge effects in single cells glass; and

FIG. 21 is a diagram showing an illustrative embodiment in which additional features are provided to the glass edge of the solar cells for optimizing light capture.

### DETAILED DESCRIPTION

Single cell encapsulation (SCE) technology according to the illustrative embodiments described below can be a plug-in solution for existing cell and/or module manufacturing lines, which enables the production of lower-cost and higher-performance PV modules, while incorporating a number of desirable features.

Standard cell manufacturing lines produce photovoltaic cells, which consist of a thin (typically approximately 180 μm) silicon wafer with front and back electrodes. The cells are very fragile and need to be handled with extreme care, and therefore breakage of the cells poses limits on the minimum practical thickness of the cell in a conventional module assembly line. On the other hand, thinner cells require less silicon material and therefore enable lower material cost. Encapsulating the cells as they leave the cell manufacturing line provides strength and protection to the fragile silicon and will enable the handling of ultra-thin (<120 μm) cells without the need for specialized equipment, reducing breakage rates without incurring additional capital equipment expenses.

During manufacturing of an integrated solar module, interconnect ribbons are soldered to the top and bottom of busbars of adjacent cells to form strings which are then laid out in a multilayer structure comprising: a bottom layer or “backsheet”, such as TPE (Tedlar, Polyster, Ethyl Vinyl Acetate (EVA)), TPT (Tedlar, Polyster, Tedlar), glass, etc.; a layer of encapsulant, such as ethylene vinyl acetate (EVA), polyvinyl butyral (PVB), silicone, polyolefin resins, polydimethylsiloxane (PDMS), polyepoxide resins, etc.; the PV cells; a second layer of encapsulant; and a transparent top layer of glass, which also provides structural integrity. The multilayer structure is then laminated in machines, which combine the layers by pressing them together for approximately 1 to 30 minutes. The lamination time depends on the type of encapsulant and on the encapsulation process, which may include application of heat, force and/or vacuum. Finally, an aluminum (or other metal, polymer, composite, etc.) frame is typically adhered to the edges multilayer structure and the electric junction box with bypass diodes is connected to the electric contacts from the strings, on the back of the module. The whole process can take up to 1 hour per module with manual assembly. Module line automation is a desirable option for manufacturers in countries with high cost of labor, however automated production lines are quite complex and expensive.

In its generalized implementation, SCE plus FMA technology includes laminating individual cells in standalone elements with mechanical, thermal and electronic properties. There are numerous advantages to this approach over current techniques as described in prior art, including for example:
1) The bottom layer material can be chosen to optimize thermal transfer, minimize cost, provide structural support or improve environmental protection.
2) The top layer (glass or other transparent material) can be constructed without regard to structural properties and can be substantially thinner since the FMA can support each individual cell, allowing for higher light transmittance, reduced module weight and lower cost.
3) Breakage from handling the cells can practically be eliminated.
4) The encapsulation of each individual cell enables a continuous process, as opposed to batch encapsulation of PV cell assemblies in current PV module lamination methods, which enables a high degree of process control, leading to:
   a. Fewer broken or damaged cells during encapsulation.
   b. High process uniformity.
   c. Lower amounts of encapsulant required per cell.
   d. Outgoing quality control (OQC) after single cell encapsulation that enables the accurate measurement of actual cell performance in the field. As a consequence, modules built with SCEs can achieve tight output power distribution at their nominal power rating. OQC before module integration also allows for the incorporation of cells into a module after all the mechanical processes have been completed, thereby reducing the probability of defective cells entering the module. Furthermore, the module manufacturing process described here also allows for the identification and removal of defective cells before final module integration, thus allowing much larger modules that improve the installation cost component of PV plants, to be manufactured. By way of example these larger modules can incorporate from 60 to 6,000 cells.
   e. Implementation of Lean Manufacturing principles which inherently lead to higher throughput and improved quality while reducing material, labor and overhead costs. The enabling and incorporation of these principles via a continuous process as well as their benefits should be well-known to those skilled in the art.
5) According to one embodiment, SCE top and bottom electrodes are laminated onto the solar cell top and bottom electrodes and held in place by either mechanical compression or conductive glue. Soldering to the cells is therefore eliminated, resulting in the following substantial advantages:
   a. Solar cell front and back bus bar width and thickness can be substantially reduced by (e.g.) approximately 40% to 100%, while maintaining low interconnection resistance, therefore saving on silver paste cost.
   b. Screen-printing of the bus bars can become unnecessary: A step is removed from the cell manufacturing line where significant breakage occurs.
   c. Recent publications suggest that the combination of thermal and mechanical stresses onto the brittle silicon during the soldering process of the interconnect ribbon onto the cell can cause the formation of micro-cracks, which in turn propagate during the lifetime of the cell, can create macro cracks and substantially degrade the solar cell performance over time. This mechanism is thought to be one of the main drivers of well-documented module performance degradation over time.
   d. The differences in coefficient of thermal expansion (CTE) of the soldering material, the copper interconnection ribbon, the silver paste and the silicon cell cause significant internal stresses on these materials during thermal cycles as will be known to those skilled in the art. A solderless process utilizing a less rigid conductive connection between the cells will enable strain movement between the layers without transfer of stresses and thereby significantly reducing degradation of cell performance over time.
   e. Soldering of solar cells can take up to one man-hour per module when manually executed: a solder-less process enables labor cost savings and achieves greater accuracy and reliability.
   f. Implementation of advanced frontal interconnects such as ribbon with a surface texture to enhance light capturing which cannot be soldered without damaging the texture and fine wire interconnects that reduce shading.
   g. Seamless integration of advanced frontal contact mechanisms such as nano silver wire.

Note, as used herein the term “standalone” or “stand-alone” in the context of the illustrative embodiments of SCEs refers to the fact SCEs are each essentially discrete, stand-alone, weatherized components and that the frame used to hold such SCEs is only (illustratively) a supporting structure with interconnections and other features. This arrangement is novel distinct from various prior art implementations, which integrate the frame as a portion of the overall system in terms of weatherization and/or other functions.

These are only some of the immediate advantages in accordance with the teachings herein; SCE is an enabling technology in a number of ways over the current architectures described in prior art:
1) The PV module becomes a flexible-format module architecture (FMA). In one illustrative embodiment, FMA comprises an uncomplicated electronic board pre-fabricated using relatively inexpensive, weather-resistant materials and embedding electric contacts and other power conditioning electronics. In another illustrative embodiment, FMA consist of a supporting frame of highly variable form-factor where SCE are mechanically secured and electrically interconnected.
2) Cells are connected in dedicated slots or pads, which is straightforward to automate.
3) The module form-factor can be highly variable:
   a. In one illustrative embodiment, a large scale FMA, in excess of 1.6 square meters, can hold a large number of SCEs to form a very large scale PV module, or mega-module. Such device can significantly reduce installation cost in large-scale photovoltaic fields or rooftops. The mega-module would be assembled at the factory and include fast mounting fixtures; it would then be transported on-site by special truck carriages, lifted by cranes and rapidly mounted on poles, trackers or other suitable structures.
   b. In another illustrative embodiment, the FMA frame would be constructed of materials to replace or augment building envelope materials and its form-factor would be dictated by architectural considerations for building-integrated photovoltaic (BIPV) or building-applied photovoltaic (BAPV). Examples of such applications are:
      i. Photovoltaic curtains of highly variable form-factors.
      ii. Photovoltaic roofs of highly variable form-factors. Including as an illustrative example the use of modified roof shingles with mounting hardware protruding from the shingle that attaches to a receptacle in the frame.
      iii. Photovoltaic rails and trims.
      iv. Individual photovoltaic tiles.
   c. In another illustrative example the frame can incorporate mounting hardware for the module such as:
      i. Mounting post receptacles
      ii. Roof mounting receptacles
      iii. Integrated receptacles for structural beams
      iv. Click in hardware
      v. Cable trays.
   d. The frame can be made from a wide variety and combination of materials allowing for the optimization of many different variables. By way of example, the frame can be optimized for strength by including fibers in the material. In another example the materials choice is such that the thermal expansion of the frame is matched closely to that of the glass so that minimal movement between cells is experienced between cold night and hot days.
   e. In other illustrative example the module frame can be such as to allow modules to be optimally stacked on top of each other to reduce space between the modules and therefore volume for shipping. Alternatively cells can be shipped separately and integrated into modules at or near the installation site.
   f. Cell electrical interconnection points can be co-molded into the frame where cells or cell strings connect directly to the embedded busbar that is protected from the environment and provide superior electric insulation and robustness since it avoids (is generally free-of) exposure to environmental conditions, especially degrading UV rays.
   g. The frame can incorporate battery cells to enable storage of charge electricity integrated into the frame.
   h. The frame can incorporate electronics that can optimize the performance of the module by controlling the output of each individual cell or the module as a whole.
   i. The frame can incorporate the junction box co-molded so that it is fully integrated. This removes the junction box connection step from the manufacturing process. This connection is usually done with a silicone adhesive. Silicone, being transparent to water vapor but insulating to water liquid allows moisture to accumulate in the junction box during the day. This moisture condenses into water when temperatures drop during the night. This accumulated water is a major source of degradation of the module terminals and can cause electrical shorting and fire when it allows contact between terminals. Some manufactures fill the entire junction box with expensive silicone to counter this failure mode. However, having the junction box as an integral part of the frame removes the failure mode all together.
4) It is unnecessary in the implementations of the embodiments herein to connect the PV cells in series, as is common practice in prior implementations: in a generalized configuration, a by-pass diode can be embedded at the cell point of contact to solve the problem of shading at the cell level. More advanced, power-optimizing solutions that even include active control can be implemented at moderate cost increase;
5) Notably, cell technology innovation and PV plant infrastructure can be decoupled: i.e. in manufacturing cells according to the embodiments herein, the cells in a PV system can be replaced when new cells become available; the old cells can be recycled in low-tier applications where lower efficiencies are tolerated: an independent, dynamic market for cells is therefore created with product differentiation instead of a fairly static and undifferentiated industry (PV panels). Likewise, it is contemplated that cells can be replaced in the field or that panels can be recycled and upgraded with newer technology without completely disposing of the old panel. Moreover, decoupling is highly desirable to fully leverage the fast cycles of cell technology innovation in renewable energy penetration (cell cycles are 5 years or less versus 20 years of infrastructure constructions);
6) Individual SCEs can be packaged more tightly for transportation;
7) Individual SCEs can be handled more conveniently for repair and recycling;
8) Individual SCEs in a module can be replaced when their performance degrades below a nominal threshold in such a way that modules built with SCEs can maintain high yield over their rated lifetime;
9) SCE technology can be applied to any types of cells, including, but not limited to:
   a. Pure semiconductors, such as Silicon, Germanium, etc.
   b. Compound semiconductors, such as Indium Gallium Arsenide (InGaAs), Indium Gallium Phosphide (InGaP), Gallium Arsenide (GaAs), etc.
   c. Thin film semiconductors, such as amorphous Silicon (a-Si), Cadmium Telluride (CdTe), Copper Indium Gallium Selenide (CuInGaSe), Lead Methyl-Ammonium Iodide (PbMAI) or similar perovskite compositions, etc.
10) SCE enables hybrid modules incorporating different cell technologies performing better in different environmental conditions.

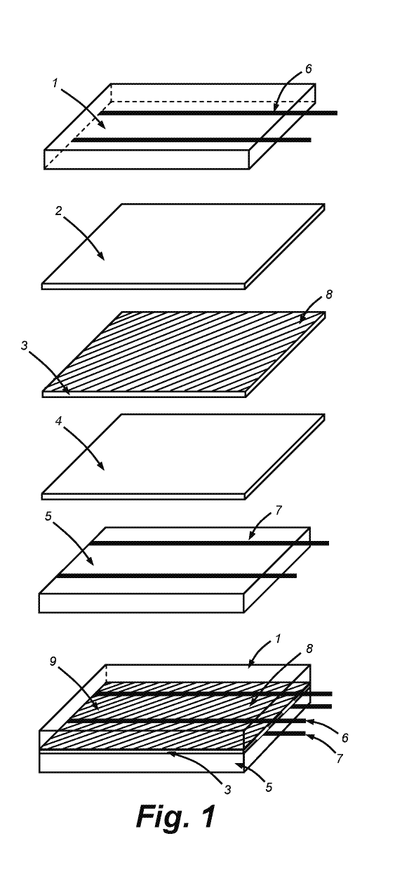

An illustrative embodiment of an integrated encapsulated solar cell (SCE) is shown in FIG. 1. SCE 9 consists of several layers that are combined during a lamination process to encapsulate and protect solar cell 3 within transparent SCE top layer 1 and SCE bottom layer 5.

As will be known to those skilled in the art, solar cell 3 is equipped with front and back electrodes, which are employed to extract the photocurrent generated by the incoming solar radiation. The cell front electrode usually comprises a large number of fingers, approximately 10 to 20 micrometers high and 50 to 200 micrometers wide, and several bus bars, approximately 10 to 20 micrometers high and 1.5 to 3-millimeter wide. The main function of the bus bars is to collect the electric current from all the fingers and to offer a soldering pad for the strips of metal, known as tabs or ribbon, which interconnect solar cells in a module. Cell top layer 8, on which the cell front electrode is formed, is usually a Silicon Nitride layer added for optical efficiency and electrical passivation. Cell top layer 8 is non-conductive and a manufacturing process is employed to make electric contact to solar cell 3 through cell top layer 8. An example of such a process is where the cell front electrode is screen-printed using a conductive paste, usually containing Silver particles. The cell is then baked at high temperature, which allows some of the paste to diffuse though the Silicon Nitride in order to make electric contact with solar cell 3. The cell back electrode usually comprises an Aluminum-based layer covering the full extent of the back of solar cell 3 and several bus bars, approximately 10 to 20 micrometers high and 3 to 5 millimeter wide. Akin to cell front electrode, the cell back electrode is usually screen-printed and baked at high temperature into solar cell 3. Alternatively, both the cell front electrode and the cell back electrode can reside on the bottom face of solar cell 3. Several methods are available for creating such a configuration, including Metal-Wrap-Through (MWT), Emitter-Wrap-Through (EWT) and Interdigitated-Back-Contact (IBC), as it is known to those skilled in the art. In an embodiment, the cell front and back electrodes are assumed to be an integral part of solar cell 3. However, it is contemplated that such electrodes can also be created during the SCE process described herein.

SCE top electrode 6 is connected with the cell front electrode and SCE bottom electrode 7 is connected with the cell back electrode, therefore guaranteeing electrical access to the cell from outside the SCE package. In one illustrative embodiment, the cell front electrode is located on the top face of solar cell 3; however, it should be clear and apparent to those skilled in the art that the scope of the various embodiments extends to other cell electrode configurations, including, but not limited to, MWT, EWT and IBC configurations, in which cases SCE top electrode 6 is relocated to the back of solar cell 3.

In one illustrative embodiment of a lamination process, SCE 9 consists of a sandwich of multiple layers that, in order, include a transparent SCE top layer 1 such as glass, acrylic, Teflon or other transparent materials as known to those skilled in the art. SCE top electrode 6, made from appropriate conducting materials such as copper, aluminum, other conductive metals and conductive non-metals whether they are transparent or non-transparent, is placed between SCE top layer 1 and cell top layer 8 of solar cell 3. SCE top electrode 6 can be integrated into SCE top layer 1 in multiple ways as known to those skilled in the art or can be a standalone layer. Top encapsulant layer 2, consisting of a thermo-set or non-thermo-set materials characterized by low Equilibrium Moisture Content (EMC) of less than 0.2% at 85 C and 85% relative humidity and by low surface tension of less than 30 mN/m, such as polydimethylsiloxanes (PDMS), is placed between SCE top layer 1 and solar cell 3. It is recognized that certain types of encapsulants can be desirable for use in the illustrative SCE architecture—for example those that are characterized by (a) very low EMC and (b) very high wetting properties. Illustratively, acceptable thresholds for these two physical parameters (a and b) can be provided. For example, the EMC was found to be 0.28% for EVA and only 0.035% for PDMS at 85 C/85% RH in a recent study by Dow Corning (See: http://onlinelibrary.wiley.com/doi/10.1002/pip.1025/abstract). Additionally, silicones have a surface tension of 20.4 mN/m, while that of EVA is in the range 30-36). See: http://www4.dowcorning.com/content/publishedlit/silicones_in_industrial_applications_i nternet_version_080325.pdf and www.vtcoatings.com/plastics.htm. The bottom encapsulant layer 4, consisting of thermo- or non-thermo-set materials of similar properties as top encapsulant layer 2, is placed between the back of solar cell 3 and SCE bottom layer 5. SCE Bottom layer 5 can be a multitude of materials chosen for a specific additional feature of SCE 9. By way of example, SCE bottom layer 5 provides weather, impact and electrical insulation to solar cell 3. In another embodiment, SCE bottom layer 5 can incorporate additional functions and processes, such as electronics, micro fluidics for cooling and purification, advanced cooling and other chemical, mechanical and electrical functions that are powered by the solar electricity generated by solar cell 3. SCE bottom electrode 7 is placed between SCE bottom layer 5 and the back of solar cell 3. SCE bottom electrode 7 can be integrated into SCE bottom layer 5 in multiple ways as known to those skilled in the art or can be a standalone layer. The lateral dimensions of the SCE can be 100-200 mm. Illustratively, the thickness of the layers can be as follows: SCE top layer 1 1-4 mm for glass, 0.13-1.3 mm for Teflon; top encapsulant layer 2 0.001-1.5 mm; solar cell 3 0.001-0.2 mm; bottom encapsulant layer 4 0.001-1.5 mm and SCE bottom layer 5 0.2-0.5 mm. The aforementioned materials and thickness values are illustrative of a wide range of possible materials and dimensions.

In the example of using thermoset materials as encapsulant, the aforementioned sandwich of multiple layers is then placed under pressure while exposing it to heat in a ubiquitous lamination process. The heat of the process initially softens and allows encapsulant layers 2 and 4 to melt and flow. By way of a non-limited example (and for which further alternate processes are described below), pressure applied to the sandwich while encapsulant layers 2 and 4 are melted, squeezes encapsulant material out between SCE top electrode 6 and cell top layer 8, allowing SCE top electrode 6 to make electric contact with the cell front electrode. Similarly flow of bottom encapsulant layer 4 under pressure allows for SCE bottom electrode 7 to make electric contact with the cell back electrode. The temperatures employed in the process are illustratively in the range of 25° C. to 1,000° C.

After sustained exposure to heat, the polymer material of encapsulant layers 2 and 4 will cross link, bonding to all material that is in contact with it. Hence, SCE top layer 1 and cell top layer 8 is illustratively bonded in a similar manner as the back of solar cell 3 and SCE bottom layer 5. However, since all encapsulant has flowed under pressure from between SCE electrodes 6 and 7, a suitable electric connection between the cell electrodes and the SCE electrodes is ensured. Because such interconnection process is solder-less, the bus bars on the front and the back of solar cell 3 can be made free of bus bars. Therefore, the width of such bus bars can be substantially reduced or the bus bars can be entirely omitted from the structure, with significant savings in conductive paste usage. The lamination bond secures solar cell 3 between SCE top layer 1 and SCE bottom layer 5, giving it the mechanical properties of the respective layers and forming SCE 9. This lamination is durable and reduces the risk that the inner layer will crack.

In one possible variation of the lamination process, SCE top electrode 6 can be placed between top encapsulant layer (also termed “encapsulant top layer”) 2 and cell top layer 8. Likewise, SCE bottom electrode 7 can be placed between bottom encapsulant layer (also termed “encapsulant bottom layer”) 4 and the back of solar cell 3.

As yet another alternative, SCE top electrode 6 can be directly attached to the cell front electrode by soldering, ultrasonic welding, conductive glue or other suitable technique, as it will appear to those skilled in the art. Likewise, SCE bottom electrode 7 can be directly attached to the cell back electrode by similar process or technique.

As will be appreciated by those skilled in the art, thermosetting is one of many processes available to bond the sandwiched layers of the SCE 9 according to an embodiment. For example in another variation of the lamination process, a PDMS (silicone) encapsulant can be used. Silicone can be tailored to cure with the addition of heat, ultra-violet light (UV) or a catalyst or a combination of the aforementioned in just a few minutes. Furthermore, silicone can be tailored to have a specific hardness and Young's modulus of choice. Commercial silicone encapsulants feature a number of properties that make them ideal for SCE, for example: High transparency; Stability to ultra-violet light; High breakdown voltage; Superior volume resistivity; Higher resistance to potential induced degradation (PID); Excellent adhesion to glass and other SCE relevant materials. By virtue of the low equilibrium moisture content and excellent weather resistance of silicone encapsulants, SCEs can be made with very small clearance between the edge of solar cell 3 and the edge of integrated SCE 9, thereby enabling a high packaging density of PV cells in PV modules. For example, current cell package density for ubiquitous modules requires 3 mm between cells. An SCE encapsulated with silicone can have an edge distance from cell to air from 0.1 mm to 1.5 mm, the latter allowing for the same packing density and module efficiency as common modules, the former increasing said efficiency. The weatherization of PV cells can be further improved by an additional layer of suitable sealant applied around the edges of SCE 9, which should be clear to those skilled in the art.

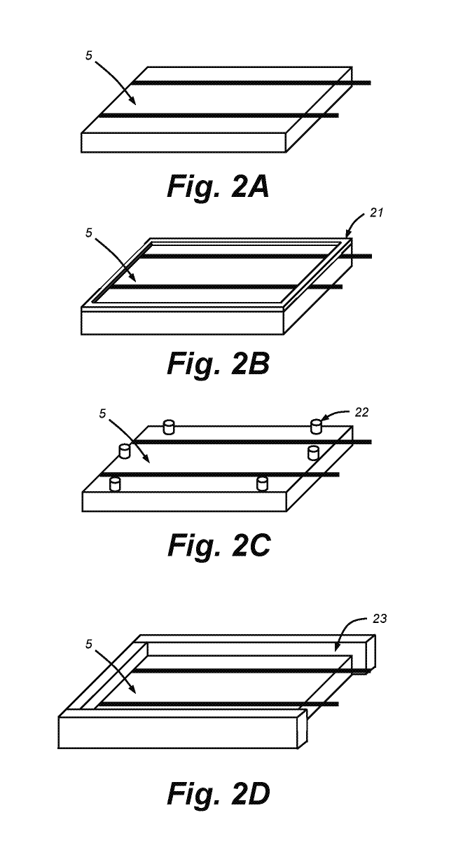

During lamination, it can be desirable to employ a physical structure to prevent layers from slipping and misaligning with respect to each other as bonding layers cure. FIG. 2 illustratively shows possible solutions implemented on SCE bottom layer 5 in order to seat the cell, facilitate the alignment of layers and avoid layer slippage during lamination. An alignment mask 21 in FIG. 2B can be superimposed onto SCE bottom layer 5 before lamination; a number of dimples 22 can either be punched, fixed into or casted into SCE bottom layer 5 as shown in FIG. 2C; or dent 23 can be created in SCE bottom layer 5 by either depressing the center, by attaching borders to the outer sides or by casting it as part of SCE bottom layer 5 (FIG. 2D). Furthermore, the restraining structures can be separate from the sandwich materials, and can be applied externally as will be known to those skilled in the art. These are a few examples and there are a wide variety of techniques to mechanically retain the cell and other layers during lamination that are clear to those skilled in the art.

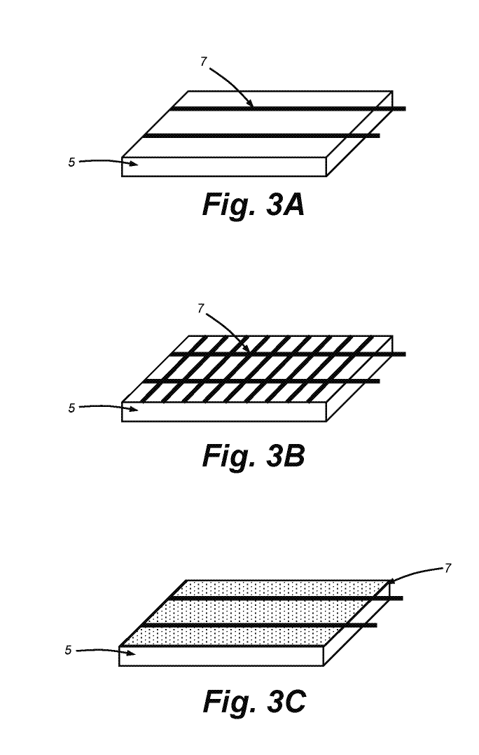

FIG. 3 illustrates SCE bottom electrode 7 superimposed on SCE bottom layer 5 in various illustrative embodiments. SCE bottom electrode 7 can be made from appropriate conducting materials such as copper, aluminum, other conductive metals and conductive non-metals that offers sufficiently low electrical resistance in order to conduct electricity with minimal losses. SCE bottom electrode 7 can be formed in a number of patterns on SCE bottom layer 5 by processes know to those skilled in the art. These include printing, plating, etching, bonding, depositing (by chemical as wells as physical processes and structures) among a wide variety of possible techniques, processes and structures. These processes allow for the electrode to take on a plurality of patterns as shown in FIG. 3. These include in a basic form one or more straight lines (FIG. 3A), a mesh or grid (FIG. 3B) or a full back contact (FIG. 3C). The choice of pattern is dependent on a number of factors such as conductivity, cost, heat transfer properties, quality of contact during lamination to name a few. Overall, SCE bottom electrode 7 has the flexibility to take on a multitude of forms from a number of materials, thereby allowing for functional flexibility that can be designed into the invention.

As an alternative, SCE bottom electrode 7 can consist of several conductive strips of metal independent of SCE bottom layer 5, also known as tabs, of the type conventionally used to interconnect solar cells in PV modules. The tabs can be located either between SCE bottom layer 5 and bottom encapsulant layer 4 or between bottom encapsulant layer 4 and the back of solar cell 3.

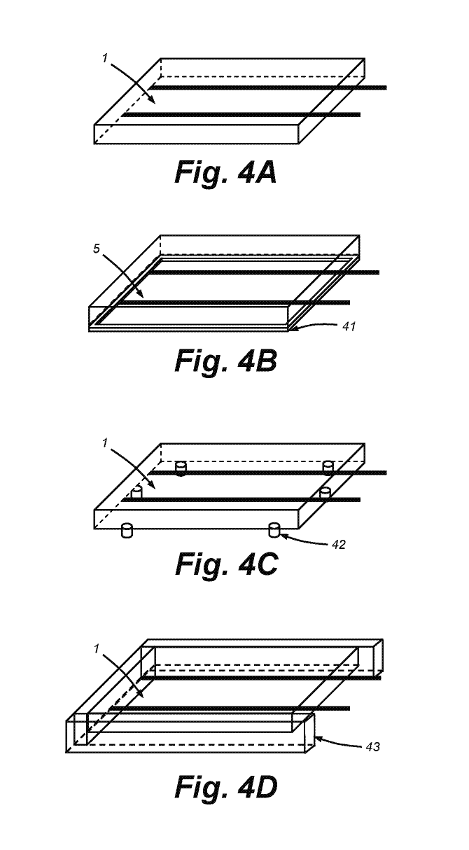

FIG. 4 shows further possible embodiments of a technique that facilitates alignment of the layers and avoids layer slippage during lamination, which are alternative to the embodiments illustrated in FIG. 2. In the present embodiments, the structures are integrated with, or connected to, transparent SCE top layer 1. As shown in FIG. 4B, an alignment mask 41 can be superimposed to SCE top layer 1 before lamination; a number of dimples 42 can either be punched, fixed into or casted as part of SCE top layer 1 as illustrated in FIG. 4C; or a dent 43 in FIG. 4D can be created in SCE top layer 1 by either depressing the center, by attaching borders to the outer sides or by casting it as part of SCE top layer 1. These implementations are illustrative of a variety of possible techniques that can be implemented by those skilled in the art.

The viscosity of the silicone encapsulant can be tailored to improve the ability to align the layers to be laminated. In some cases, the viscosity can be adjusted within the silicone encapsulant formulation. In other illustrative embodiments, the silicone can be partially cured to increase viscosity. Partial curing can be accomplished by the application of a moderate amount of UV light, moderate heat for a short time, or a minimal amount of time exposure to controlled humidity, depending on the type of curing required for the specific encapsulant formulation.

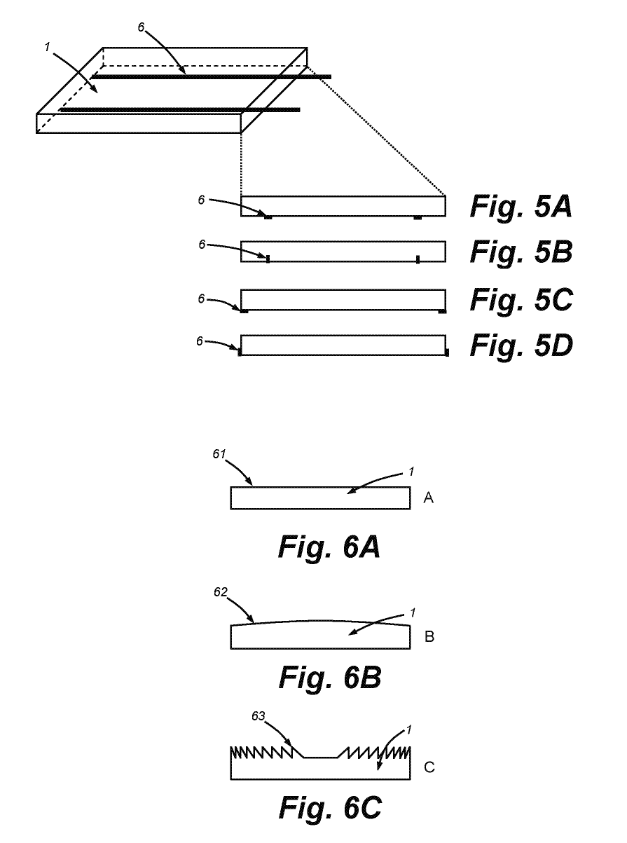

SCE top electrode 6 serve to conduct electricity generated from the solar cell 3. However, when made from non-transparent material, they also reduce the amount of light that penetrates cell top layer 8, thereby effectively reducing the efficiency of solar cell 3. In FIG. 5, SCE top electrode 6 can be integrated as part of SCE top layer 1 though processes such as printing, plating, etching, bonding, depositing (by chemical as well as physical mechanisms and techniques) and a variety of other processes, or can be a standalone layer, many combinations and methods that should be clear to those skilled in the art. These methods allow for flexibility in the electrode design to allow for minimal electric losses though the electrodes while maintaining high solar cell efficiency. FIG. 5 illustrates a plurality of arrangements that take advantage of the flexibility offered by the numerous techniques available to create SCE top electrode 6.

In one embodiment as illustrated in the cross section of FIG. 5A, SCE top electrode 6 is a flat (planar), straight substrate superimposed on transparent SCE top layer 1 (a “flush orientation”). In another embodiment, as shown in the cross section of FIG. 5B, SCE top layer 1 has been created with cavities such that SCE top electrode 6 can be inserted (embedded) into the layer as a vertical substrate and resides relative flush with one side thereof (a “vertical embedded orientation”). These vertical substrates allow for SCE top electrodes 6 with high frontal area and thus low resistance but minimal blocking of light or shadowing of the solar cell, especially when used in combination with a tracker. Another possible embodiment includes configuring electrodes at the corners of SCE top layer 1 as shown in the cross section of FIG. 5C such that SCE top electrode 6 is only casting a shadow on the solar cell during certain parts of the day (an “edge orientation”). In yet another embodiment, SCE top electrode 6 is placed on the side of SCE top layer 1 as shown in the cross section of FIG. 5D (a “side orientation”). SCE top electrode 6 still protrudes from the bottom of SCE top layer 1 so that electric contact will be made with the solar cell during lamination.

As an alternative, SCE top electrode 6 can consist of a plurality of conductive strips of metal independent of SCE top layer 1, also known as tabs, of the type conventionally used to interconnect c-Si cells in PV modules. The tabs can be located either between SCE top layer 1 and top encapsulant layer 2 or between top encapsulant layer 2 and cell top layer 8.

In a further alternate embodiment/example, to minimize front surface shading, SCE top electrode 6 can consist of a single strip of interconnect material, including without limitation a light capturing ribbon, a fine metal or nanowire mesh or a conventional interconnect ribbon situated at the edge of the cell connecting perpendicular to and connection all of the conductive silver fingers. This arrangement may be facilitated by the addition of one or more fine conductive silver fingers spaced across the solar cell perpendicular to the primary conductive silver fingers and connecting them electrically.

Traditional PV modules incorporate a multiplicity of cells in one final assembly step. A large transparent layer, typically glass (but alternatively a durable, weather-resistant and UV-stable polymer), resides on top of the cells. Traditionally, this transparent layer has been of rectangular cross section. This cross section is an optimization of structural and cost features. Since the transparent layer of SCE is a single piece of material for each encapsulated cell, and is generally free of system-wide structural requirements, it can define a wide variety of shapes to optimize the optical efficiency of the device. In one embodiment as shown in the cross section of FIG. 6A, SCE top layer 1 has a traditional flat (planar) surface 61. However, the material thickness can be substantially reduced since the structural requirements of the SCE are significantly lower than that of an entire module. The cross section of FIG. 6B illustrates another embodiment of SCE top layer 1 that defines a non-planar shape on at least one side thereof. Here surface 62 is convex, allowing for light that enters it to be bent and light paths to be optimized. In yet another embodiment, SCE top layer 1 has a Fresnel (or functionally similar geometry) lens 63 integrated in it as shown in FIG. 6C. The Fresnel lens allows for light to be deflected based on the design of the lens. The aforementioned shapes serve as an illustration of the flexibility in cross sectional shape that SCE allows for SCE top layer 1. The possible benefits of utilizing these or other shapes for optimizing light paths are well known to those skilled in the art. By virtue of the significantly smaller unsupported area than prior implementations, SCE top layer 1 achieves the same mechanical stability as the front glass of conventional photovoltaic modules, at substantially reduced thickness and possibly constructed free of any tempering or other hardening processes. Reduced thickness and elimination of additional processing steps for the top glass can result in substantial cost savings and will improve light transmittance and efficiency.

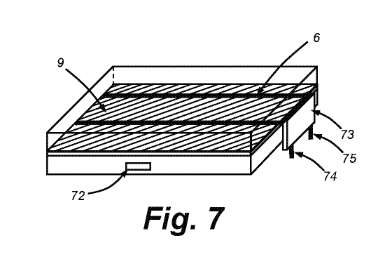

To increase design flexibility of the SCE, it can be desirable to incorporate mechanical arrangements for structurally and electrically coupling the SCE to other SCEs in a module. In FIG. 7 an illustrative embodiment of such connections is shown. Electric connector 73 is a weatherized pin connector such as those made by Molex Corporation of Lisle, Ill. These connectors allow for electrodes to be mechanically secured, stress relieved, electrically insulated and protected from the environment through an interface that provides standard connections to the outside world. Connector 73 has a positive pin 74 and negative pin 75, connected to SCE top electrode 6 and SCE bottom electrode 7 respectively. The standard electric interface allows for the SCE to be connected to any circuitry also from a third party vendor by just specifying the mating connection. It is further contemplated that arrangements for electrically connecting cells can be provided within the FMA structure and need not be integrated within the SCE. Mechanical slot 72 is an example of how the SCE will be mechanically connected to a supporting structure. In this example, a lock pin slides into slot 72 and secures and anchors SCE to the supporting structure as will be apparent to anyone skilled in the art.

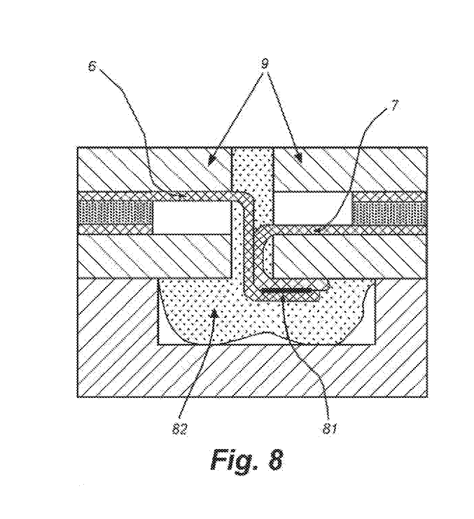

FIG. 8 illustratively shows a side cross section of an embodiment in which the SCE top electrode 6 is directly connected to SCE bottom electrode 7 of an adjacent SCE to form interconnection 81. Interconnection 81 is illustratively weatherized using an electrically insulating material 82, which can consist of silicone gel, shrink wrap or other suitable materials that provide high electric resistance and protect the connection from the elements. A number of methods are available to create reliable interconnections such as soldering, ultrasonic welding, crimping, etc., which are well known to those skilled in the art. The shape of interconnection 81 is just one of a wide variety of layouts, where a path is created in order to comply with mechanical deformations of SCE and FMA components.

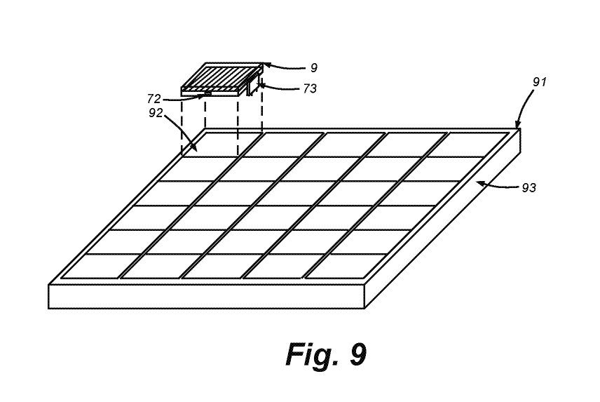

FIG. 9 illustratively shows a Flexible-format Module Architecture (FMA) and how SCEs fit into such architecture by employing the structural and electrical connections described above. FMA 91 can consist of a supporting frame (or substrate) 93, which can be made of various weather-resistant metals, composites, plastics (for example PET, fiber reinforced PPE+PS, etc.), and other materials, with many manufacturing processes of said materials, such as extrusion, cold and hot pressing, injection molding and others, as it will be apparent to those skilled in the art. In another embodiment, FMA 91 can consist of a grid-like structure 93 with cross section optimized to withstand the mechanical load and stresses on the PV module.

In one possible embodiment, FMA 91 incorporates slots 92 for mechanical connection 72 and electrical connection 73 of SCE 9. In another illustrative embodiment, adjacent SCEs are directly connected to one another, as shown and described above in FIG. 8, and subsequently anchored to slots 92 by mechanical connectors, glue, friction fit, thermal compression or other suitable techniques known to those skilled in the art.

SCEs 9 can be inserted in the FMA 91 by a ubiquitous pick-and-place robot, widely used in the automation industry, and implemented in accordance with ordinary skill. These robots are able to move and insert SCEs 9 rapidly and precisely, without causing breakage due to the mechanical resistance of individually encapsulated cells. Alternatively, SCEs 9 can be directly connected to one another to form strings and strings can be subsequently mounted and interconnected on FMA 91.

FMA 91 can also incorporate electrical interconnections between cells, electrical interconnections between strings of cells and power conditioning electronics, both at the cell level and at the module level. As an illustrative example, electrical by-pass diodes can be co-molded at each SCE in order to isolate individual SCEs in case of partial shading or failure. More generally, the FMA can include electrical connections that interconnect predetermined of the cells together, the electrical connections including bypass diodes constructed and arranged to enable inoperative cells and cells that are functioning poorly (e.g. shaded cells or degraded cells) to be bypassed in an overall electrical connection of the cells. As another illustrative example, the junction box containing string-level electrical by-pass diodes can be incorporated in FMA 91 by co-molding it into the structure. Alternatively, each cell's positive and negative electrode can be wired to the junction box where sophisticated cell level power optimization electronics can regulate the power generated by each cell. These are just some of a wide variety of implementations of FMA-integrated power conditioning electronics according to various non-limiting examples and embodiments.

Furthermore, FMA 91 can include a plurality of mounting solutions (not shown), which allow seamless and low-cost integration of the module in a photovoltaic power plant. Such mounting solutions can be posts, pedestals, holes, screws, interlocking mechanisms, ballasts, and many others, as it will be apparent to those skilled in the art.

One of the advantages of SCE 9 and FMA 91 is the flexibility of electrical configurations attainable for PV cells. Electrical interconnections built into FMA 91 can have a larger cross section and lower resistance than those of conventional PV modules, because they do not fall in the light path and can avoid being routed in the tight spaces between neighboring cells. In one embodiment, electric connections departing from SCE electrodes 6 and 7 of all SCEs 9 in FMA 91 converge into a central electronic board where they are interconnected in series, parallel or hybrid configuration, with or without power conditioning electronics, as it will be clear to those skilled in the art. In an alternate embodiment, each SCE 9 is connected directly to its immediate neighboring cells and the power conditioning electronics is located on or near SCE 9.

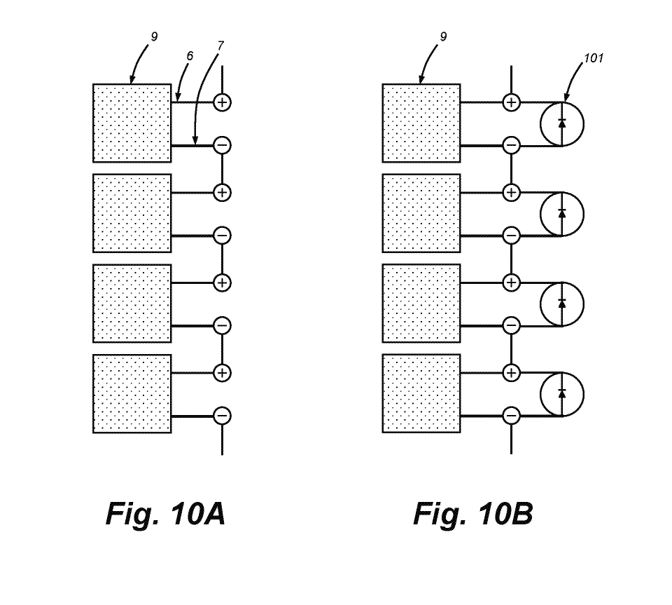

In one embodiment of the circuitry of FMA 91, SCEs 9 are connected in series (FIG. 10) as is common with solar modules based on current implementations: SCE top electrode 6 of each cell is connected to SCE bottom electrode 7 of the neighboring cell either directly or by using a conductor housed inside FMA 91. FIG. 10A shows a basic series configuration, while FIG. 10B shows a series configuration with power conditioning electronics added in parallel to each cell. By way of example, bypass diodes 101 can be added between SCEs 9 to address one of the biggest problems in PV modules: When one cell's performance is degraded by fouling, cracking or other eventualities, it affects the entire system's power output because the cell can dissipate power instead of generating it. The addition of bypass diodes 101 between cells negates the influence of individual cells performance on the module performance and is one possible technique to increase module performance in real-life operating conditions. In certain embodiments of the invention, individual defective SCEs can be disconnected and replaced by new SCEs in order to guarantee high yield of the module for its rated lifetime.

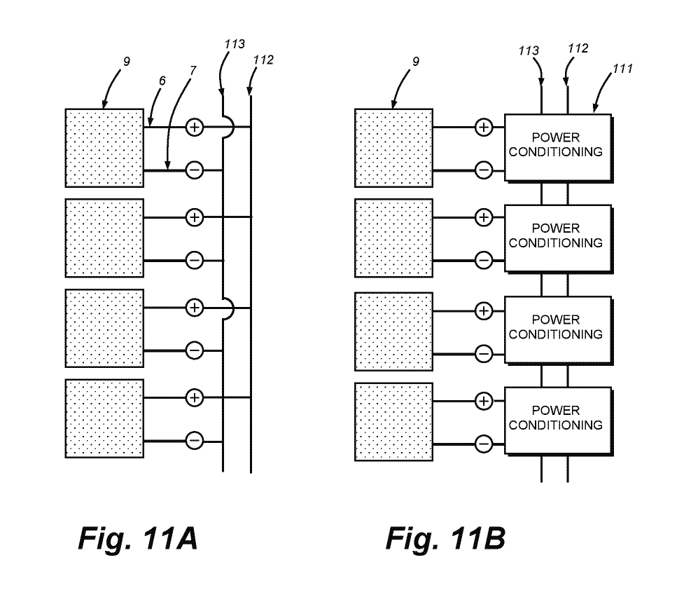

In another embodiment, FMA 91 circuitry connects SCEs 9 in parallel as shown in FIG. 11. SCE top electrodes 6 of all cells are connected to bus bar 112, while SCE bottom electrodes 7 are connected to bus bar 113. FIG. 11A shows a basic parallel configuration, while FIG. 11B shows a parallel configuration with power conditioning electronics 111 at the cell level: power conditioning electronics 111 receives the current and voltage between SCE top electrode 6 and SCE bottom electrode 7 as an input, modifies said current and applies output current and voltage to bus bars 112 and 113. In one embodiment, power conditioning electronics 111 can include one stage of maximum power point tracking, which changes the operating point of SCE 9 to optimize the power output, and one stage of DC-DC power conversion, which steps up the operating voltage, all of which are understood by those skilled in the art. In another embodiment, power conditioning electronics 111 can execute DC-AC conversion at the cell level and output an AC signal to bus bars 112 and 113.

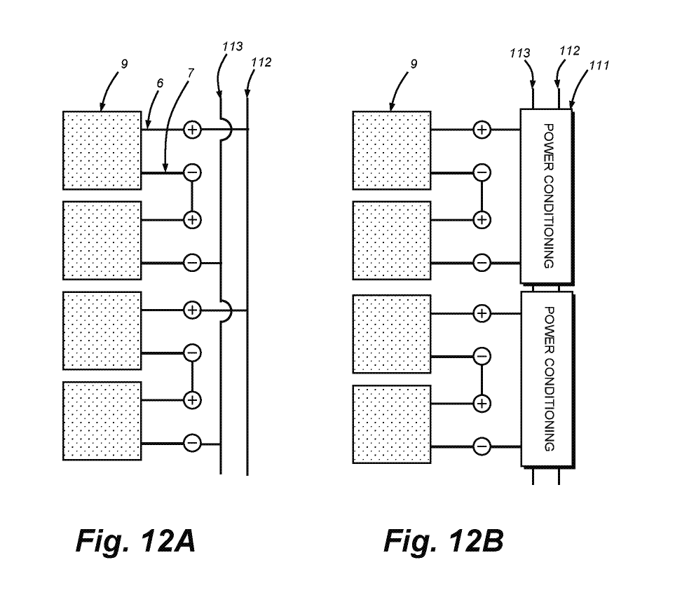

FIG. 12 illustrates another embodiment of application of flexible electronic architecture. Here a hybrid series-parallel connection of SCEs 9 in FMA 91 is illustrated: sub-groups of SCEs 9 are connected in series and the resulting circuits are then connected in parallel. FIG. 12A shows a generalized hybrid configuration, while FIG. 12B shows a hybrid configuration with power conditioning electronics 111 at the sub-group level.

It should be clear that SCE, FMA and methods for constructing the same, according to the illustrative embodiments described herein, provide a flexible-format module architecture to be implemented at the cell level. This enables cost reduction and improved performance of photovoltaic power generation.

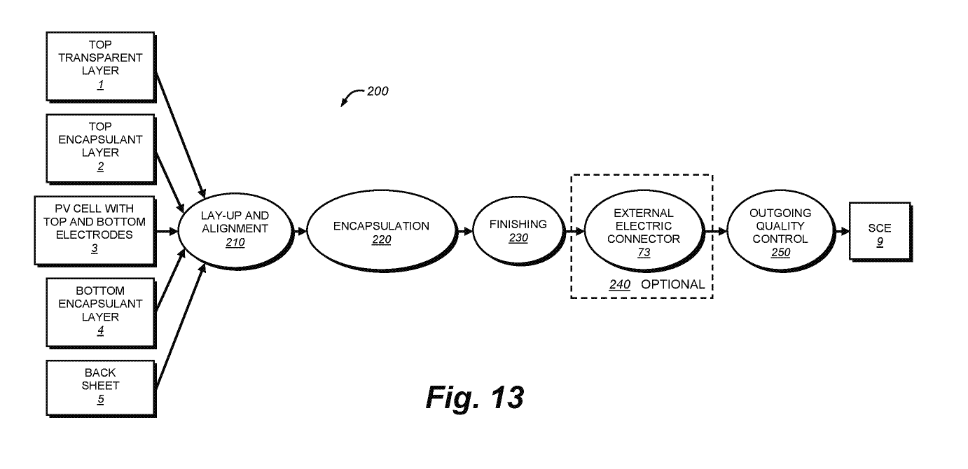

FIG. 13 illustrates a sequence of steps or functions in a process 200 to enable one possible fabrication method which might be implemented to create the SCE. In this illustrative embodiment, the process begins with lay-up and alignment of components (step 210), which have been previously manufactured. In this step, the SCE top electrode (6, described above) is connected to the front electrode of solar cell 3 and SCE bottom electrode (7) is connected to the back electrode of solar cell 3. Solar cell 3 is of the type of PV commercially available from solar cell manufacturers, however the amount of material for the cell bus bars can be substantially reduced when conductive glue, conductive tape or other solder-less interconnection methods are applied. During layup of the SCE, the cell is aligned with SCE top layer 1, top encapsulant layer 2, bottom encapsulant layer 4 and SCE bottom layer (back sheet) 5. The multi-layer structure is then encapsulated (step 220), for example by pressing and heating under vacuum or exposing to ultraviolet radiation or other forms of catalytic agents, for a sufficient amount of time, depending on the materials used and according to practices known to those skilled in the art.

External electric connector 73 can be optionally applied (step 240) and the cell is finished into SCE 9 (step 230). A final outgoing quality control inspection (step 250) can be applied to sort SCE's by measured properties such as: total conversion efficiency, spectrally resolved conversion efficiency, light reflectance, micro-crack analysis (e.g. electroluminescence), mechanical properties, thermal characteristics, lumped electric parameter characteristics (resistance, capacitance and inductance), DC and AC electric characteristics of the junction, current-voltage response (IV curves) at different irradiances and temperatures, and other measurements known to those skilled in the art. By performing outgoing quality control after encapsulation (and generally before mounting into a PV module), an accurate estimate is obtained of the real performance of the cell in the field. As a consequence, modules built with SCEs can achieve tight output power distribution at their nominal power rating.

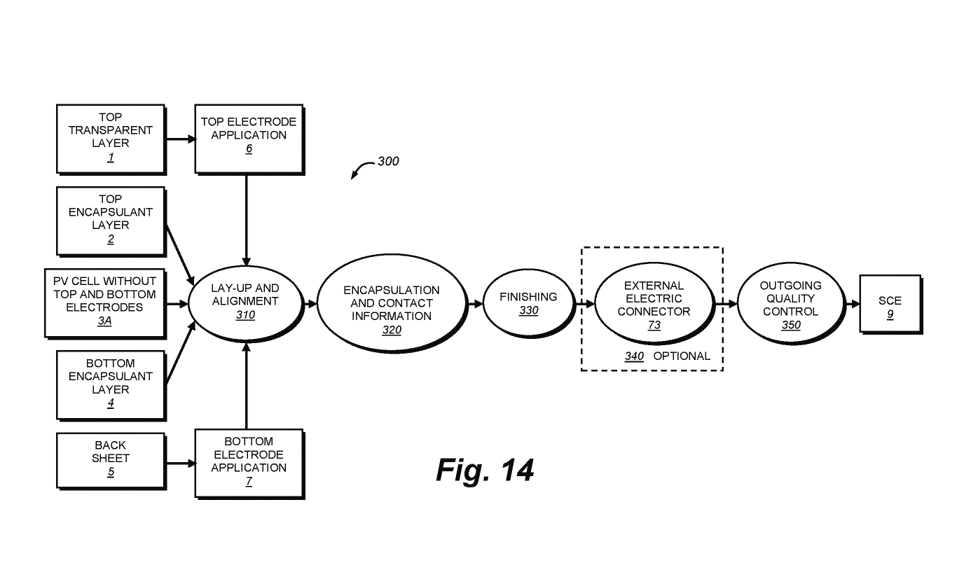

FIG. 14 shows yet another illustrative embodiment of steps in an illustrative manufacturing method. In this embodiment, SCE top electrode 6 and SCE bottom electrode 7 are first applied in the layup step 310 electrically connected to the front and back electrodes of solar cell 3A during encapsulation. In a particular case of such embodiment, solar cell 3A can be free of the front and back electrodes and such electrodes can be created during encapsulation, for example by diffusion of a suitable conductive paste through the front and back of solar cell 3. External electric connector 73 can be optionally applied (step 340), and the cell is finished (step 330) into SCE 9. The cell can then be subjected to an outgoing quality control inspection (step 350) and sorting as previously described.

In an illustrative embodiment using silicone encapsulants, the silicone can be dispensed between the front surface tabs and the front transparent layer and the back surface tabs and the back sheet. Due to the small area of the SCE, the silicone can be dispensed in multiple macroscopic parallel lines, in a radial pattern or even as a single application near the center of the application surface, rather than requiring a uniform coating of less than 450 microns, making encapsulant dispense a more robust process. The silicone can be dispensed in the amounts necessary to form a layer that is thinner than a 400-500 micron state of the art EVA encapsulant. With the use of a low viscosity silicone material, the laminate stack can be pressed to final thickness by uniform axial compression or by passing the assembled stack through a set of rollers or by application of vacuum compression or other processes known to those skilled in the art. The application of pressure to the stack will disperse the applied silicone encapsulant to the desired final thickness. The laminate stack can then be cured to ensure adhesion and cross linking of the silicone encapsulant without the continuous application of pressure. In the case of a low viscosity silicone encapsulant, the applied encapsulant will flow easily to the desired final thickness, so it may be desirable to partially cure the encapsulant to decrease the viscosity or to complete the cure of the encapsulant with the continued application of pressure.

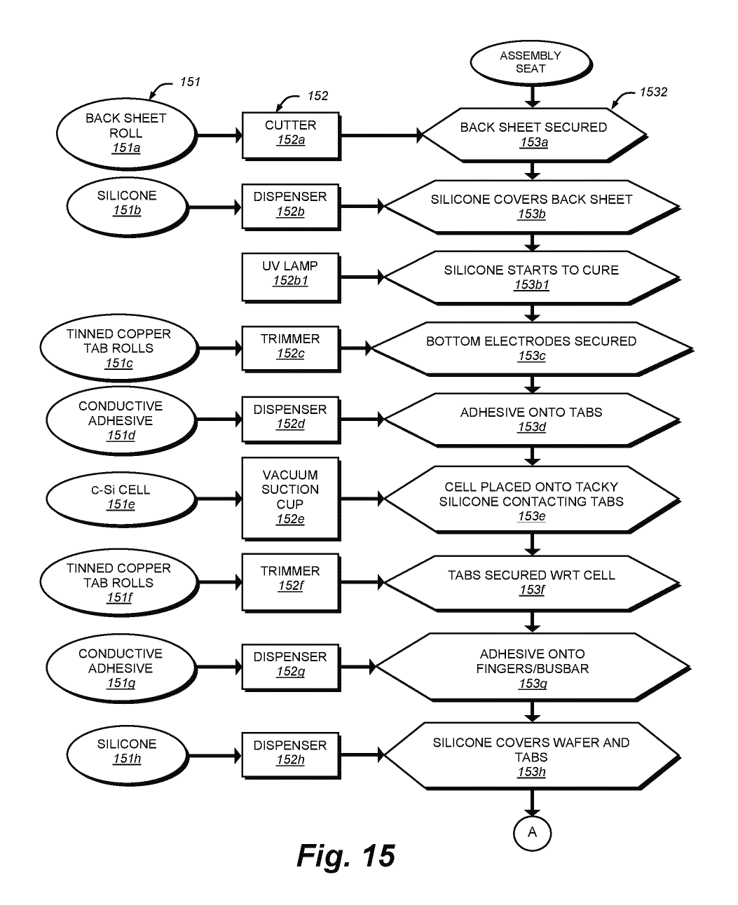

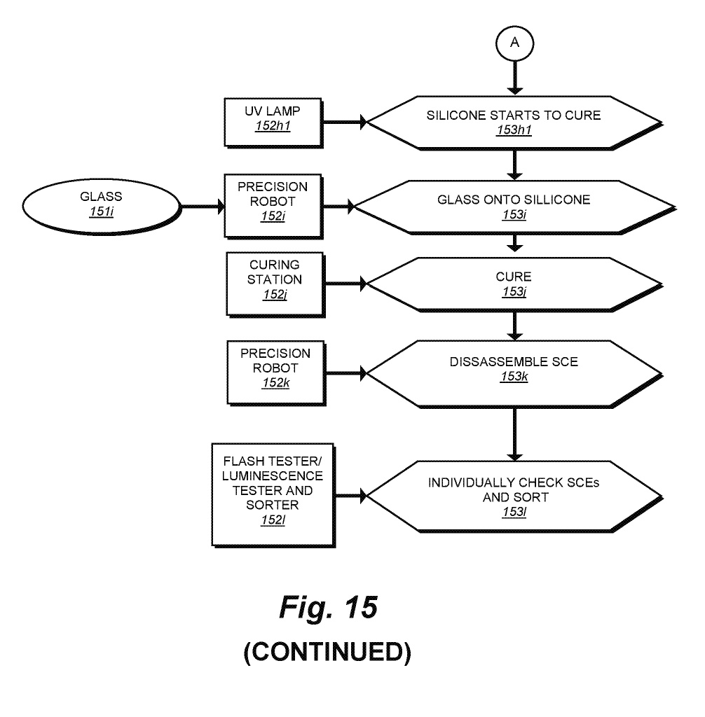

FIG. 15 illustrates an example of manufacturing steps employed when utilizing silicone as the encapsulant as described above. In this example input materials 151 is represented by an oval, processing tools 152 by a rectangle and manufacturing steps 151 by a hexagon. The process depicted in FIG. 15 utilizes UV curing, however, as is well understood by those skilled in the art, Silicone can cure by a number of means, temperature, humidity etc. and vacuum is an optional addition to the manufacturing process when silicone is the encapsulant. The process in FIG. 15 utilizes an assembly seat 154 to house the SCE assembly during curing. This is specific to the illustrative/exemplary method/process of FIG. 15 and entirely optional. Back sheet can be supplied on a roll 151a and is added/secured (step 153a) to the bottom of the assembly seat after it is cut to length by a cutter 152a. Silicone 151b is then dispensed by a dispenser 152b onto the back sheet so as to cover it (step 153b). In this example, the silicone formulation allows it to be cured by exposure to UV light 152b1, therefore a UV lamp is shone onto the silicone to start the curing process (step 153b1). The silicone in this example will cure in a short time to a stiff rubber, but will undergo a transition in viscosity from runny to tacky to fully cured stiff rubber. As the silicone starts to cure, the copper tabs sourced (e.g.) from a roll 151c are trimmed by a trimmer 152c and secured on top of the silicone as bottom electrodes (step 153c). A dispenser 152d dispenses a measured amount of conductive adhesive 151d onto the trimmed tab 153d after which a silicon cell (also termed a wafer during the process of construction) 151e is added to the assembly by a precision robotic arm utilizing a vacuum cup 152e. The cell is placed (step 153e) such that its back and busbars (if present) comes into direct mechanical contact with the conductive adhesive such that a low resistance electrical contact is formed between the cell and the copper tab. The conductive adhesive can be of a plurality of products that are available off-the-shelf and known to those skilled in the art and also cure with methods know to those. Conductive adhesive 151g is added (step 153g) to the cell's fingers or busbars (if present) via a dispenser 152g. Copper tabs are sourced from (e.g. a roll 151f) trimmed to length using a trimmer (152f) and placed so that they make direct mechanical contact with the conductive adhesive so that a low electric resistance bond is formed between the fingers of the cell and the busbars if present (step 153f). Silicone 151h is then dispensed over the entire assembly (step 153h) by a dispenser 152h and then exposed to UV rays (step 152h1 via a UV lamp 153h1. The glass 151i is then added to the top of the assembly (step 152i) by a precision robot 152i upon which the assembly enters the curing station to be cured (step 153j). In the case of UV curing the assembly will remain in curing for the duration specified by the manufacturer of the particular silicone encapsulant. However, the curing station can incorporate heat, humidity and any other factor that will allow or increase the rate of curing of the silicone. After the encapsulant has cured, or reaches the recommended amount of curing (step 153j) that allow the cells to be processed, a precision robot will disassemble the assembly and remove the SCE (step 153k). After removal the SCE will undergo Outgoing Quality Control (OQC) inspections (step 153l) that can include a flash tester 1521 and sorter and any other OQC processes commonly used by the industry such as electro-luminescence, resistance, I-V curve, efficiency, fill factor etc.

It should be noted that FIGS. 13, 14 and 15 show only three exemplary/illustrative processes/methods out of a number of potential, illustrative methods for encapsulation that incorporate lamination to manufacture SCE. Other suitable methods of encapsulation include depositing, spraying or painting a layer of suitable materials on one or both sides of solar cell 3, with or without SCE electrodes 6 and 7, with or without SCE top layer 1 and SCE bottom layer 5. Many such materials and methods exist, which produce suitable encapsulation to protect the cell from environmental conditions, as will be known to those skilled in the art. One common characteristic of many such methods is the possibility of adopting a continuous process for single cell encapsulation as opposed to the industry's standard practice of laminating large PV cell assemblies in batches, with significant advantages in terms of process control, reproducibility and yield.

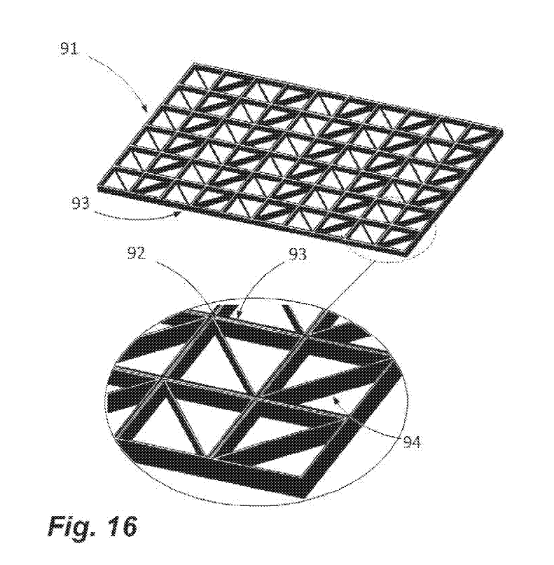

FIG. 16 illustrates another exemplary/illustrative embodiment of the FMA. Here FMA 91 consists of several features that can be manufactured by a number of methods such as 3D printing, injection molding, blow molding, open-die compression molding, vacuum molding, machining, sand casting, extrusion and joining or any other process known to those skilled in the art. FIG. 16 show that supporting sub-structure, frame or framework 93 includes slots 92 that align individual SECs for connection to the sub-structure, as well as internal beams 93 that can run in vertical or horizontal directions, or both as illustrated and are sized and formed specifically to support the weight of the cells and FMA under all loads the system will experience in the field. These loads include snow, construction personnel, wind and others known to those skilled in the art. Additionally the sub-structure can also include additional features and members such as beams for structural rigidity as shown. Alternatively the beams and members can be optionally angled for preference in thermal expansion direction. Furthermore the sub-structure can be manufactured from many different materials and combination of materials to optimize, with its design, the functionality and response of the system to environmental conditions. For instance, utilizing glass cloth or glass fibers or carbon fibers oriented in preferred directions will reduce the amount the sub-structure will deflect due to thermal expansion in that direction. More generally (as described elsewhere herein), in accordance with skill in the art the sub-structure can be constructed partially or entirely from non-metallic materials, and can be generally free of metallic components, such as steel or aluminum alloy. The layout in accordance with the depiction of FIG. 16 is but one illustrative example to indicate the design flexibility of the FMA and its ability to be custom designed and manufactured for specific purposes.

PV module weight influences the cost of a PV power plant in many ways. For one, structures need to be suitably large and strong to accommodate the modules. In the case of roof mounted systems, pre-installed roofs often need additional bracing to support a PV system. Secondly larger equipment, more labor and increased power is required to move, lift and install heavier modules. Thirdly, it is more costly to ship heavier items. It is therefore desired to make lower weight PV modules. PV module weight is largely driven by the glass (front and back when applicable) and sub-structure materials. One of the advantages of making a FMA 91 sub-structure 93 from composite materials is that the composite sub-structure can be designed and optimized to bear substantially the required load of the PV system, a function shared between the glass and sub-structure of current module designs. Since sub-structure 93 can be optimized for minimum weight with required strength it is possible to remove the burden of structural integrity from the glass. Therefore the SCE can implement thinner glass since the glass sheet is smaller and since it does not need to be part of the structural backbone of the module. By utilizing the sub-structure in this manner weight savings of (e.g. approximately 20% and more is achievable. Even higher weight reduction is possible when the front protection of the PV cell is made from a transparent material other than glass that has a lower density. These materials such as PTFE and PCB are utilized today in specialty modules and should be known to those skilled in the art.

Modules built with SCE's and incorporating an FMA sub-structure can reduce input material costs. Cell busbars fabricated from silver paste act mainly as soldering pads to connect tabs. When utilizing conductive adhesive, substantial cost savings is enabled by reducing the amount of silver paste used in the busbars, both in the front and the back of the cell. Since the FMA sub-structure is designed to bear all the required loads of the module, the glass of the SCEs can be thinner, saving on material cost. Since the price of glass drops as thickness decreases from today's module standard of approximately 3.2 mm down to approximately 1.9 mm and then becomes more expensive as the thickness reduces further, the currently most cost effective glass thickness is approximately 2 mm. Sub-structures formed from engineering materials with new processes are generally less expensive than aluminum frameworks. The smaller area of the SCE requires less encapsulant to fill up voids due to misalignment of the back sheet/glass and front glass, saving between 15% and 60% on encapsulant volume. Lastly, when silicone is used as the encapsulant, the module edge area can be 1 mm instead of the current 20-25 mm. This allows an average 1.0 m by 1.6 m module to be reduced in size by (e.g.) approximately 6%, saving proportionally on glass, back sheet and encapsulant.

A number of examples are provided herein to illustrate the design flexibility and the number of useful features that are obtained by using a specifically manufactured sub-structure. These examples are illustrative of but not limiting to the possibilities that exist in utilizing a custom sub-structure versus the traditional aluminum sub-structure utilized in PV modules today.

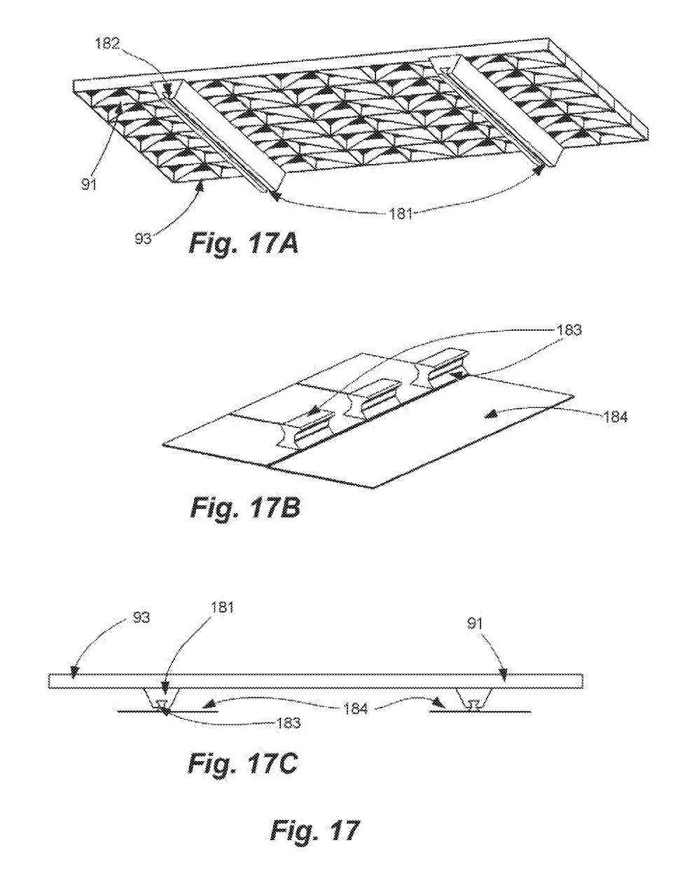

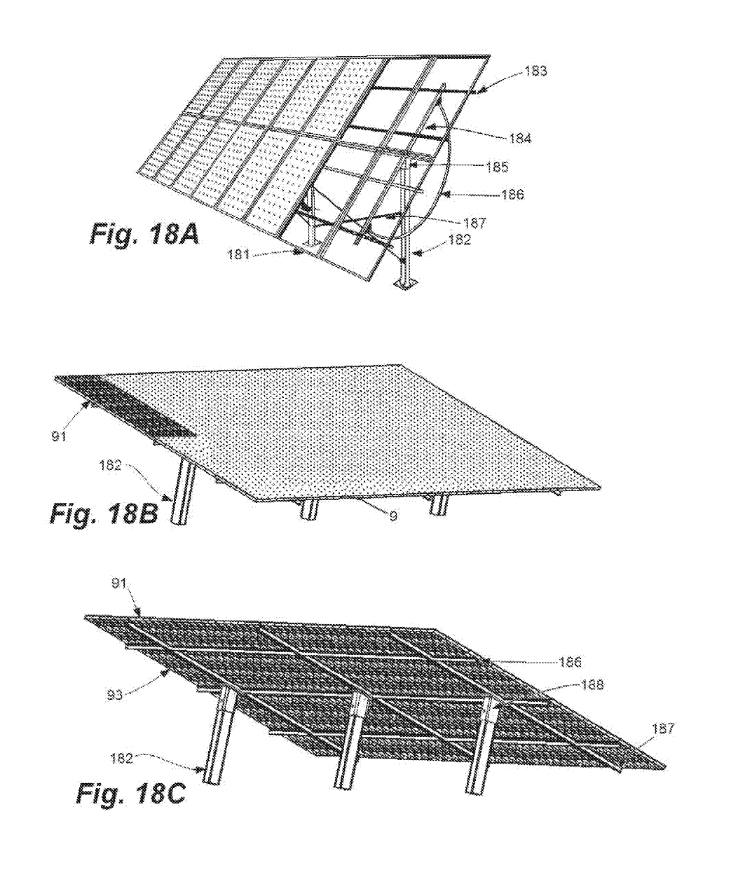

As a first example of useful features, consider the components illustrated in FIG. 17. In FIG. 17 an FMA 91 consists again of supporting sub-structure 93 that is designed to house the SCE's and support mechanical loads. FMA 91 also incorporates roof mounting receptacles 171 that can be co-molded with supporting sub-structure 93. Receptacles 171 can include formed slots 172 that can receive a mounting fixture of similar shape. Such a mounting fixture 173 is shown integrated onto a flange designed to be used much as a ubiquitous composite, asphalt or polymer (or other conventional) roofing shingle 174 in FIG. 17B. Such mounting flanges can be formed of polymers, inorganic materials, metal or composite sheets that can be secured to the roof of a structure by driving screws or other fasteners through the flange and the roof sheathing into the rafters, by adhesives and any other form as will be well known to those skilled in the art. Attachment in this way avoids (is free of) penetration of the roofing shingle(s), and instead secures the flange directly into the supporting structure of the roof, reducing part count, reducing installation time and forming a more secure mount than a conventional mounting rail system. Mounting fixtures 173 can define a number of configurations including various cross sectional shapes adapted so that they can slide into FMA 91 formed slots 172, securing sub-structure 93 to flange 184 as shown in FIG. 18C, and thus, to a roof when flange 184 is secured to the roof. This illustrative example illustrates a straightforward method of securing a PV module to a roof with minimal labor effort, minimal part count as should be clear to those skilled in the art. The mounting flange can also be fabricated at different heights to provide an optimal tilt to the module when installed on a sub-optimal roof pitch so that the module optimizes the relative angle of incident sunlight during the day as known to those skilled in the art. The flange can include wiring systems that interconnect modules and remote power connections that tap the array of modules and deliver power to a user (e.g. a building and/or dwelling). The wiring system can employ conductive flat leads, wires and/or other appropriate conductive conduits (e.g. conductive ink/paint). Similar designs can be used on flat roofs to provide module tilt and can be attached to the roof by adhesives, ballasted or affixed by other means to avoid the penetration of the roofing material by mounting bolts. Such designs can include various framework members and associated supporting structures and/or wedge-shaped blocks that both support and provided desired angular tilt to the module relative the flat roof.

As another illustrative example of the utility of the FMA, refer to FIG. 18A showing an illustration of a modern ground mount system's racking according to a conventional arrangement. As shown, the racking system consists of mounting post 182 that is typically driven deep into the ground (and/or provided with a heavy footing), and forms the backbone of the structural support of the system. Horizontal and vertical beams 183 and 184 are bolted to mounting post 182 via receptacle 185 and beam support structure 186. Further structural support elements 187 complete racking system 181. Standard PV modules are slid onto horizontal beam 183 and fixed to the beams with additional mounting hardware including nuts and bolts as known to those skilled in the art. In general, a certified or skilled electrician is often employed to connect each individual module's input and output cables to a string during installation. A considerable portion of the total PV power plant cost is associated with the design, evaluation, construction and materials needed to erect racking system 181.

FIGS. 18B and 18C illustrates a functionally similar system to that depicted FIG. 18A, populated with FMA 91, is shown in FIG. 18B. In this arrangement, the entire racking system is part of sub-structure 93 that includes all of the horizontal 186 and vertical 187 structural beams, as well as receptacle 188 that slides onto mounting post 182 and can be secured by a single bolt. PV cells (SCE 9) are already integrated into the FMA 91. Thus the factory pre-assembled modules can be lifted as a unit and placed onto posts with no additional labor other than securing the bolts and securing the entire system to the posts. It is also contemplated to include the wiring and wiring trays, already connected to each other so that a single power connection can be made to the entire large system. Alternatively the modules can be made with the structural beams included in each individual module and these modules can then be connected to each other at the site. Mechanical connection can be achieved via bolting, adhesives or click-together receptacles designed into sub-structure 93. Horizontal 183 and vertical 184 structural beams can be present in individual modules and connected on site. Alternatively, the sub-structure 93 can have slots and receptacles that will allow extruded beams to slide into the modules and secured by mechanisms known to those skilled in the art to form the structural backbone of the installed string. Electrical connection between individual modules can be made via an integrated connector male and female present on each module. Alternatively each module will have a junction box and junction wires protruding from it as in a conventional module. Sub-structure 93 can provide cable trays and connection points for these wires in order to ease installation. Alternatively busbars can be co-molded inside the sub-structure to conduct electricity to the main junction box.

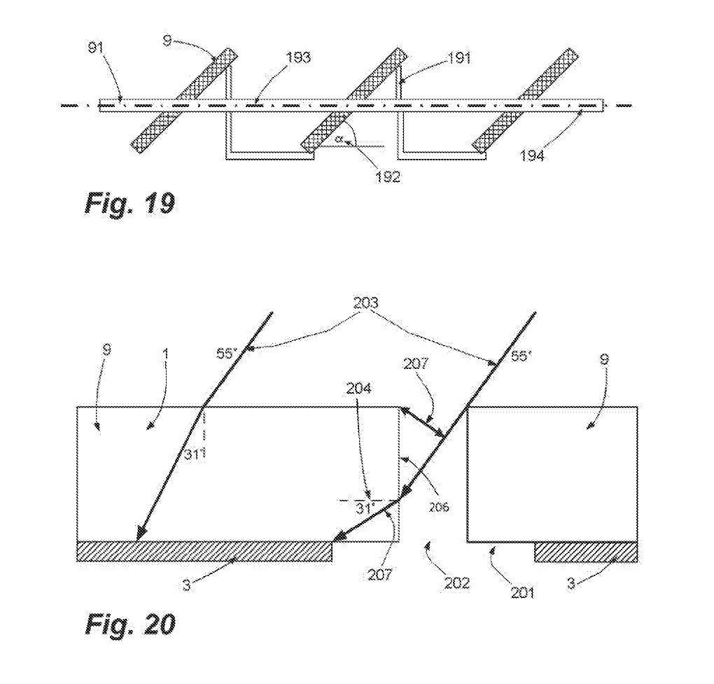

FIG. 19 illustrates the utility of the FMA in tracking applications. By mounting PV modules on a tracker that follows the motion of the sun, a substantial increase in the yield or energy production of the PV module can be achieved. Illustratively, at least two distinct tracking systems, employing techniques generally known to those skilled in the art can be employed. These include: Dual axis trackers that follow the sun from sunrise in the east to sunset in the west and also adapt for the shift in azimuth due to the changing tilt of the earth on a daily basis; and Single axis trackers only follow the sun from sunrise to sunset and usually incorporate modules that are mounted horizontally with respect to the north-south direction. Fixed-tilt systems are usually titled in the north south direction at an optimal angle that is calculated with the latitude of the installation among other variables as will be known to those skilled in the art. Typically, dual axis trackers add on the order of, for example, approximately 25-35% and single axis trackers will add approximately 10-15% to the cost to a system when compared to fix tilt, however these numbers are highly dependent on the specifics of the project. Illustratively, for a specific location in Kimberley, South Africa, single axis tracking adds, for example, approximately 23% and dual axis tracking adds, for example, approximately 36% increase in yearly solar energy yield when compared to optimally inclined panels. However a single axis tracker that utilized panels inclined at 30°, very close to the optimal fixed tilt angle, increases yield by ˜31% over fixed tilt. Refer by way of useful background information to Suri M., Cebecauer T., Skoczek A., Solar Electricity Production from Fixed-inclined and Sun-tracking c-Si Photovoltaic Modules in South Africa. 1st Southern African Solar Energy Conference (SASEC 2012), 1-23 May 2012, Stellenbosch, South Africa. Undesirably, a primary driver of the low-cost of single axis tracking is the fact that the modules are horizontally mounted because it reduces the complexity of installation and reduces the burden on the tracking motors since both the center of gravity and the center of aerodynamic pressure is located at the center of rotation as will be well understood by those skilled in the art. It is, thus, highly desirable to provide a system that combines the low cost of installation and hardware of a single axis tracker with the performance of an optimally inclined single axis tracker.

FIG. 19 is an illustrative example/embodiment how the use of SCE and the FMA can obtain the desired combination of optimally inclined single axis tracking with the hardware and installation cost of horizontal single axis tracking. SCEs 9 are installed in FMA 91 which consists of sub-structure 93 that has mounting slots 191 such that SCE 9 can be inclined at optimal angle 192 that is determined for the specific location of the PV power plant as will be known to those skilled in the art. By mounting SCE's as shown the combination of SCEs 9 and sub-structure 93 can maintain their center of gravity 193 in the same plane as that of the center of rotation 194 of the tracker. Thus, the tracking system employs a relatively small, incrementally increased amount of work due to the slight increase in moment of inertia of the inclined cells, but does not demand the substantial increase in the amount of work required to rotate a module that has a center of rotation offset from its center of gravity as will be the case when conventional modules are to be used as known to those skilled in the art. In addition, the weight reduction achieved through the use of thinner glass on SCE 9 because of the structural load absorbance of sub-structure 93, will cause a smaller increase in moment of inertia than when conventional materials were used for a similar layout. Thus, utilizing a layout such as the one depicted in FIG. 19, it is possible to utilize the same tracking and mounting equipment as used in a horizontal-mounted, single-axis tracker, with its cost benefits, but get the performance increase of an optimally-inclined, single-axis tracker system.

The previous examples serves as illustrate examples of how FMA 91 can be designed and manufactured as to meet specific customer requirements and needs. These examples are far from exhaustive and only serve to illustrate how the flexibility of the architecture achieved by combining SCE 9 and FMA 91 can be customized to solve a number of real life issues and cost drivers for the industry. A few further examples are listed for illustration. These include: very large modules with hundreds of cells can be made because cells that are defective can be found during the OQC process and replaced before the large module leaves the factory; Non-conventional module shapes are possible. For instance triangular or smaller rectangular shapes that can fill the space left empty by the restrictive conventional module size on a rooftop; Modules integrated into structural and/or decorative elements of a building that enable cost effective BIPV; Optimally inclined rooftop systems where the angle of the cells will be optimal regardless of the angle of the roof; Various mounting hardware solutions that can reduce the logistical, labor and part count burden currently imposed onto installers by conventional architecture; Lightweight car ports, building facades, awnings and other building features can be designed with SCE 9 incorporated into the sub-structures; and/or specialty systems for cars, boats, RV's and other mobile vehicles can be designed to incorporate SEC 9.

A significant feature of FMA 91 is that sub-structure 93 can be made from non-electrically-conductive materials. The use of non-conductive materials for the sub-structure reduces the need for grounding modules, removing the significant expense of both the copper wire and ground penetrating hardware as well as the labor associated with grounding modules. Another driver for installation cost is the maximum voltage that the string can operate on. Maximizing the voltage of the system reduces the current that conductors need to carry and therefore reduce their cross sectional area, size and cost. The industry is currently moving toward 1,000V systems with a strong desire to extend that to (e.g. approximately) 1,500V. The use of silicone as encapsulant in combination with non-electrically conductive sub-structure 93 increases both the di-electric strength as well as the electric resistivity of the module. These attributes are currently lacking in conventional modules and are considered to be enabling for the drive to 1,500V strings as will be known to those skilled in the art. Volume resistivity is also a contributing factor to a degradation mechanism that is becoming more important for the longevity of solar PV plants: Potential Induced Degradation or PID. Higher voltages, grounded modules and the use of lower di-electric strength and volume resistivity EVA has contributed significantly to PID degradation as will be known to those skilled in the art. Thus the use of advanced materials with its superior electric qualities has the potential to reduce PID and extend PV power plant life as well increased energy output over time.

Increased module efficiency is a highly desired feature. Higher efficiency results in more electric energy production for the same input cost and therefore lower levelized cost of electricity (LCOE) as known to those skilled in the art. The combination of SCE and FMA provide a gain of, for example, approximately 1.4% absolute efficiency when compared with conventional modules utilizing the same cells. Efficiency is defined as the amount of power generated by the cells divided by the product of the module size and the sunlight delivered to the module per square meter. Thus to increase module efficiency, more power must be generated by the module, the module size must be reduced or the amount of sunlight captured and absorbed by the module should increase.

The drivers for the efficiency gain of the combined SCE and FMA system are the following: Silicone is transparent to lower wavelength, ultraviolet (UV), sunlight whereas EVA absorbs UV light. Therefore more sunlight is delivered a cell encapsulated by silicone; Thinner glass reflects less sunlight and thus also allows more sunlight to pass onto the cells; As discussed earlier, the smaller encapsulation edges possible with silicone allows the module area to be smaller, also increasing efficiency.

A standard module has cells laid up next to each other with a 3 mm spacing between the cells. This spacing is a function of the di-electric strength and volume resistivity of the encapsulant, EVA. However, in one embodiment of the SCE, it is encapsulated by silicone, with a 1 mm edge. In FIG. 20, SCE 9 is shown with top layer 1 extending 1 mm over cell 3 to from edge 201. Second, similar SCE 9 is laid up next to first SCE 9 with similar edge 201 of 1 mm with 1 mm air gap 202 between the cells. When the SCE 9 are exposed to incoming solar rays 203 that are not perpendicular to the surface of glass 1, some sunlight will enter side 206 of top layer 1. Here it will be refracted a certain mount toward perpendicular line 204 according to the refraction index of the material of top layer 1. Therefore incoming solar ray 203 will be refracted toward solar cell 3 to a new angle and direction and will become internal ray 205. Therefore a significant amount of sunlight can be captured and directed toward the cell 3 to produce power whereas in a conventional module this sunlight will only fall into gap 202 and will not contribute to the production of electric energy. FIG. 20 illustrates one example where top layer 1 is glass, 2 mm thick. In this specific instance any incoming solar ray 203 that is at an angle of 55° or more with respect to the surface of the glass will be refracted off side 206. With the refractive index of glass, the 55° incoming solar ray 203 will be refracted so that internal ray 205 will have an angle of 31°. Utilizing trigonometric relations known to those skilled in the art it can be shown that an additional 0.8 mm of light is captured along the entire edge for each of the cells.

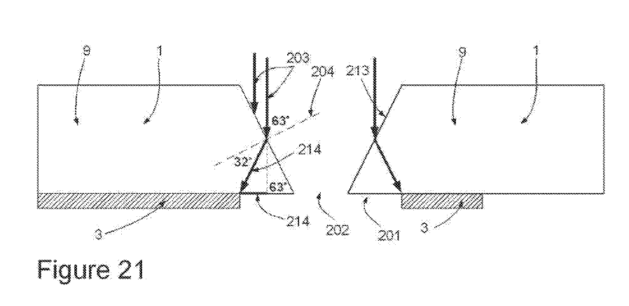

FIG. 21 is another illustrative embodiment/example of increasing the efficacy of solar cell light capture of the SCE 9 based upon its edge. SCE 9 is incorporated in an FMA that is coupled to a tracker that ensures that solar ray 203 is always perpendicular to top layer 1. SCE is configured with top layer 1 having edge 201 extending 1 mm over cell 3. In this configuration there is also a 1 mm gap between adjacent SCEs 9. Top layer 1 has side 213 beveled angle 212 over edge 201. When incoming solar ray 203 hits side 213, incoming ray 203 is refracted according to the refraction index of top layer 1 material. The refracted ray 214 angles into solar cell 3 and is captured and converted to electricity. In one particular example top layer 1 is 2 mm thick glass, bevel angle 212 is 60° and edge 201 is 1 mm. Utilizing the refraction index of glass and simple trigonometry it can be shown by anyone skilled in the art that incoming ray will have an angle of 32° into cell 3 and that there will be an effective increase in solar capture edge of 214 of 0.62 mm per edge.

In support of the industry effort to reduce the cost of photovoltaic energy and become competitive with fossil fuel generation, the flexible-format module architecture based on individually encapsulated cells enables significant savings by moving to thinner and cheaper SCE front layer materials; reducing the amount of encapsulant needed; eliminating the external sub-structure of the PV module; and substantially reducing the amount of conductive paste required for the cell front and back bus bars. Furthermore, fast-curing silicone encapsulants are especially suited for single cell encapsulation and enable high-throughput, compact machines with a level of complexity and cost substantially reduced with respect to standard manufacturing equipment. Finally, single cell encapsulation can be implemented in continuous processes, with obvious benefits in terms of process control, reproducibility and yield.

The foregoing has been a detailed description of illustrative embodiments of the invention. Various modifications and additions can be made without departing from the spirit and scope of this invention. Each of the various embodiments described above can be combined with other described embodiments in order to provide multiple features. Furthermore, while the foregoing describes a number of separate embodiments of the apparatus and method of the present invention, what has been described herein is merely illustrative of the application of the principles of the present invention. For example, the sizes, shapes and form factors of components described herein can be varied to suit a particular application. Likewise, additional layers, enclosures, housings and mounting assemblies can be employed in conjunction with SCEs and FMAs as appropriate. Also, while orientational terms such “top”, “bottom”, “left”, “right”, “upper”, “lower”, “upward”, “downward”, “forward”, “rearward”, “front”, “rear”, and “back” are employed, these should be taken as relative only and not in reference to a global coordinate system such as the acting direction of gravity. Additionally, where the term “substantially”, “about”, or “approximately” is employed with respect to a given measurement, value or characteristic, it refers to a quantity that is within a normal operating range to achieve desired results, but that includes some variability due to inherent inaccuracy and error within the allowed tolerances of the system. Moreover, materials used for encapsulant and other components are described by way of non-limiting example, and it is expressly contemplated that other materials that may be developed and/or are known to those of skill in the art having similar performance and properties can be substituted for the above-described materials. Accordingly, this description is meant to be taken only by way of example, and not to otherwise limit the scope of this invention.

What is claimed is:

1. A mounting structure for a solar PV module comprising:
a mounting assembly constructed and arranged to be attached to a rooftop free of penetration of the rooftop weatherization layer.

2. The mounting structure of claim 1 further comprising a sheet-shaped foot with one or more locking members configured to lock into a solar module.

3. The mounting structure of claim 1, wherein the mounting structure is constructed and arranged to replace conventional rooftop weatherization structures.

4. The mounting structure of claim 2 constructed and arranged to be located under an existing composite shingle and physically attached to a supporting structure of the rooftop.

5. The mounting structure of claim 2 constructed and arranged to be attached to the rooftop by adhesively bonding to the weatherization layer.

6. The mounting structure of claim 2 constructed and arranged to be attached to the rooftop by fastening through the sheet-shaped foot, into an underlying structure of the roof and beneath the rooftop weatherization layer so as to be free of penetration of the weatherization layer.

7. The mounting structure of claim 2 wherein the sheet-shaped foot is constructed and arranged to conform to a profile of a clay tile roof for mounting thereto.

8. The mounting structure of claim 2 in which the locking members respectively define differing heights to allow the module to be mounted with a tilt in a favorable position with respect to a position of the sun.

9. The mounting structure of claim 1 wherein the mounting structure includes a composite material.

10. The mounting structure of claim 9 where the composite material includes a thermoplastic.

11. The mounting structure of claim 10 where the thermoplastic is PET.

12. The mounting structure of claim 9 wherein the composite material includes glass fibers.

13. The mounting structure of claim 12 wherein the glass fibers are continuous.

14. The mounting structure of claim 12 wherein the glass fibers are chopped with an aspect ratio of length-to-diameter greater than approximately 10.

15. The mounting structure of claim 9 wherein the composite material is resistant to ultraviolet (UV) light.

16. The mounting structure of claim 9 wherein the composite material is flame-retardant.

17. The mounting structure of claim 1 further comprising solar cells that are individually encapsulated before integration into a sub-structure, the sub-structure being operatively connected to the mounting structure.

18. A method for encapsulating solar cells comprising the steps of:
providing a source of silicone encapsulant; and
applying silicone to the solar cells in an amount that efficiently generates a layer of encapsulant on each of the solar cells, whereby an amount of silicone utilized for the encapsulant provides an economically viable production process.

19. A method for continuous encapsulation of solar cells comprising the steps of:
encapsulating individual solar cells; and
inspecting and qualifying the encapsulated solar cells before integration into a PV module.
